(19) United States
(12) Patent Application Publication
(10) Pub. No.: US 2026/0029473 A1
(43) Pub. Date: Jan. 29, 2026

(54) PHYSICS INFORMED MACHINE LEARNING MODELS FOR PREDICTING BATTERY PERFORMANCE

(71) Applicant: Iontra Inc, Centennial, CO (US)

(72) Inventors: Maureen Petterson, Golden, CO (US); Ryan Wu, Denver, CO (US); Manoj K. Koul, Allen, TX (US)

(21) Appl. No.: 19/279,949

(22) Filed: Jul. 24, 2025

Related U.S. Application Data
(60) Provisional application No. 63/675,030, filed on Jul. 24, 2024.

(51) Int. Cl. G01R 31/367; G01R 31/3842; G01R 31/389; G01R 31/392

(52) U.S. Cl. CPC G01R 31/367; G01R 31/3842; G01R 31/389; G01R 31/392

(57) ABSTRACT

A system and method are provided for predicting battery-performance information (e.g., remaining useful life (RUL), state of health (SOH), and/or state of charge (SOC)) for battery based on cycling data. For example, the battery-performance information can be predicted using machine learning (ML) models that predict battery-performance information for the battery based on cycling data and electrodynamic parameters (EDPs) that are generated either by calculating the EDPs using probing waveform data or predicting the EDPs from cycling data. The ML model can have been trained using results from a physics-based model when calculating the loss function used for training the ML model.

### CROSS-REFERENCE TO RELATED APPLICATION

This application claims priority to U.S. Provisional Patent Application No. 63/675,030, filed Jul. 24, 2024, entitled “PHYSICS INFORMED MACHINE LEARNING MODELS FOR PREDICTING BATTERY PERFORMANCE,” the entire disclosure of which is hereby incorporated by reference, for all purposes, as if fully set forth herein.

### TECHNICAL FIELD

Embodiments of the present invention generally relate to systems and methods for using one or more machine learning (ML) models to predict battery-performance information (e.g., remaining useful life (RUL), state of health (SOH), and/or state of charge (SOC)) for a battery based on cycling data and electrodynamic parameters (EDPs) that are generated either by calculating the EDPs using probing waveform data or predicting the EDPs from cycling data.

### BACKGROUND AND INTRODUCTION

Battery powered devices have proliferated and become ubiquitous. Device manufacturers are constantly pressing for performance improvement in batteries, particularly as batteries are introduced into devices with relatively higher current demands and power needs. At the same time, consumers demand longer battery life, longer times between charges, and shorter charge times. As such, there is an ongoing and continuous need for improvements in how batteries are managed, charged, and discharged to enhance performance. It is with these observations in mind, among others, that aspects of the present disclosure were conceived.

### BRIEF DESCRIPTION OF THE DRAWINGS

In order to describe the manner in which the above-recited and other advantages and features of the disclosure can be obtained, a more particular description of the principles briefly described above will be rendered by reference to specific embodiments thereof which are illustrated in the appended drawings. Understanding that these drawings depict only exemplary embodiments of the disclosure and are not therefore to be considered to be limiting of its scope, the principles herein are described and explained with additional specificity and detail through the use of the accompanying drawings in which:

FIG. 1A illustrates a block diagram of an example of a configuration of a system for using a physics-based model to aid in training a machine learning (ML) model to predict battery performance from cycling data, in accordance with some embodiments.

FIG. 1B illustrates a block diagram of an example of a configuration for using the system and trained ML model in FIG. 1A to predict battery performance from cycling data, in accordance with some embodiments.

FIG. 2A illustrates an example of intra cycling data, in accordance with some embodiments.

FIG. 2B illustrates an example of inter cycling data, in accordance with some embodiments.

FIG. 2C illustrates an example of electrodynamic parameters (EDP) calculated from a probing waveform, in accordance with some embodiments.

FIG. 2D illustrates an example of parameters for a physics-based model (e.g., PyBAMM), in accordance with some embodiments.

FIG. 3 illustrates a flow diagram of a method using the trained ML model in FIG. 1B to predict battery performance from cycling data, in accordance with some embodiments.

FIG. 4A illustrates a block diagram of an example of a configuration of a system for training another ML model to predict electrodynamic parameters (EDP) from cycling data, in accordance with some embodiments.

FIG. 4B illustrates a block diagram of an example of a configuration for training and using an ML model to predict battery performance from cycling data and from EDPs predicted using the another ML model of FIG. 4A, in accordance with some embodiments.

FIG. 5 illustrates a flow diagram of a method using the trained ML model in the configuration of FIG. 4B to predict battery performance from cycling data, in accordance with some embodiments.

FIG. 6A illustrates a plot for an example of EDPs (e.g., Lyapunov exponents) predicted using an EDP ML model, in accordance with some embodiments.

FIG. 6B illustrates a histogram plot of an example of Lyapunov exponents (LE) predicted using an EDP ML mode, in accordance with some embodiments.

FIG. 6C illustrates a scatter plot of an example of Lyapunov exponents (LE) predicted using an EDP ML mode, in accordance with some embodiments.

FIG. 7A illustrates a scatter plot of an example of predicted battery-performance information (e.g., state of charge (SOC)) predicted using an ML model that is independent of EDPs, in accordance with some embodiments.

FIG. 7B illustrates a scatter plot of an example of predicted battery-performance information (e.g., SOC) predicted using an ML model that depends on predicted EDPs, in accordance with some embodiments.

FIG. 8A illustrates a block diagram of an example of a configuration of a system for training a machine learning (ML) model to predict battery performance from cycling data, in accordance with some embodiments.

FIG. 8B illustrates a block diagram of an example of a configuration for using the system and trained ML model in FIG. 8A to predict battery performance from cycling data and fixed EDP values, in accordance with some embodiments.

FIG. 8C illustrates a block diagram of an example of a configuration for using the system and trained ML model in FIG. 8A to predict battery performance from cycling data and updated EDP values, in accordance with some embodiments.

FIG. 9 illustrates a flow diagram of a method using the trained ML model in the configuration of FIG. 8B or FIG. 8C to predict battery performance from cycling data, in accordance with some embodiments.

FIG. 10A illustrates a scatter plot of predictions of the state of health (SOH) for a battery in which the true capacity of the battery is represented along the vertical axis and the horizontal axis represents the capacity predicted by an example ML model that uses only cycling data as inputs, in accordance with some embodiments.

FIG. 10B illustrates a scatter plot of predictions of the SOH for a battery in which the true capacity of the battery is represented along the vertical axis and the horizontal axis represents the capacity predicted by an example ML model that uses both EDP values and cycling data as inputs, in accordance with some embodiments.

FIG. 11A illustrates an example of a block diagram of training an AI processor to segment/identify/modify elements in the graphic narrative, in accordance with some embodiments.

FIG. 11B illustrates an example of a block diagram for using a trained AI processor to segment/identify/modify elements in the graphic narrative, in accordance with some embodiments.

FIG. 12 illustrates a block diagram of an example of a computing device that can implement the systems and methods disclosed herein, in accordance with some embodiments.

### DESCRIPTION OF EXAMPLE EMBODIMENTS

Various embodiments (also possibly referred to as examples or implementations) of the disclosure are discussed in detail below. While specific implementations are discussed, it should be understood that this is done for illustration purposes only. A person skilled in the relevant art will recognize that other components and configurations may be used without parting from the spirit and scope of the disclosure.

### Overview

In some aspects, the techniques described herein relate to a method that predicts battery-performance information for a battery, the method including: applying both cycling data and electrodynamic parameters to a machine learning (ML) model, and, in response, outputting battery-performance information, wherein the cycling data is measured during charging and/or discharging of the battery to provide some power to a load. Cycling data may be obtained during use of the battery in some application such as power tools, various mobile devices such as scooters, e-bikes, and vehicles, or obtained when operating on a battery cycler.

In some aspects, the techniques described herein relate to a method, wherein the ML model has been trained on training data that includes measured battery-performance information associated with corresponding training input data including training electrodynamic parameters and training cycling data, the training data being obtained from a corpus of historical measurements.

In some aspects, the techniques described herein relate to a method, wherein the measured battery-performance information is a metric derived from measurements of respective batteries used to generate the corpus of historical measurements, and the metric selected from the group including a state of charge (SOC) metric, a state of health (SOH) metric, and a remaining useful life (RUL) metric.

In some aspects, the techniques described herein relate to a method, wherein: the ML model is trained by adjusting weights in a neural network to minimize a loss function that includes a first term and a second term, the first term representing a distance metric between the measured battery-performance information and the battery-performance information that is output from the ML model in response to applying the corresponding training input data, and the second term representing a distance metric between the simulated battery-performance information and the battery-performance information that is output from the ML model in response to applying the corresponding training input data.

In some aspects, the techniques described herein relate to a method, wherein the electrodynamic parameters are determined based on measurements when a probing waveform is applied to the battery.

In some aspects, the techniques described herein relate to a method, wherein the electrodynamic parameters are based on one or more Lyapunov exponents corresponding to respective frequency ranges, one or more correlation dimensions, one or more sample entropies, one or more Hurst exponents, a fluctuation analysis, and/or a charge rate voltage slew.

In some aspects, the techniques described herein relate to a method, wherein the probing waveform periodically transitions from a charging period to a resting period and/or discharging period, during the charging period a voltage applied to the battery has a first pulse shape that on average is monotonically rising, and during the resting period and/or the discharging period the voltage applied to the battery has a second pulse shape that on average is monotonically falling.

In some aspects, the techniques described herein relate to a method, wherein the first pulse shape and the selected pulse shape are selected to include frequencies within a predefined range based on a frequency dependance of an impedance of the battery.

In some aspects, the techniques described herein relate to a method, wherein the corresponding training data further includes simulated battery-performance information generated by a physics-based model that predicts the simulated battery-performance information using the cycling data.

In some aspects, the techniques described herein relate to a method, wherein the loss function includes a weighting term that determines a contribution of the first term relative to the second term, and a value of the weighting term is empirically derived to minimize non-physical predictions by the trained ML model.

In some aspects, the techniques described herein relate to a method, wherein the physics-based model is selected from the group consisting of PYBAMM, COMSOL, DUALFOIL, FASTDEN, LIONSIMBA, and M-PET.

In some aspects, the techniques described herein relate to a method, further including: applying the cycling data to another ML model, and, in response, outputting the electrodynamic parameters that are applied as inputs to the ML model, wherein the another ML model has been trained using training data to predict the electrodynamic parameters, the training data including training cycling data associated with corresponding probing waveform data, and the another ML model having been trained by adjusting weighting coefficients in a neural network to optimize a loss function that represents a distance metric between electrodynamic parameters predicted based on the train cycling data and electrodynamic parameters calculated from the corresponding probing waveform data.

In some aspects, the techniques described herein relate to a method, wherein the cycling data includes current measurements, voltage measurements, and/or temperature measurements.

In some aspects, the techniques described herein relate to a method, wherein the cycling data is constant current constant voltage charging data in which, during charging a currant applied to the battery is maintained constant until a threshold voltage is reached and then a volage applied to the battery is maintained constant until charging is complete.

In some aspects, the techniques described herein relate to a method, wherein the battery-performance information includes a state-of-charge (SOC) metric, a state-of-health (SOH) metric; and/or a remaining-useful-life (RUL) metric.

In some aspects, the techniques described herein relate to a method, further including: receiving type information representing a type of the battery, and selecting the ML model from a plurality of ML models based on the type information, wherein the type information includes information representing a cathode material, an anode material, and/or an electrolyte.

In some aspects, the techniques described herein relate to a method including: applying cycling data to an ML model; and in response to the cycling data, outputting, from the ML model, electrodynamic parameters, wherein the cycling data is measured during charging and/or discharging of the battery, and the ML model has been trained using training data to predict the electrodynamic parameters.

In some aspects, the techniques described herein relate to a method, wherein: the training data includes training cycling data associated with corresponding probing waveform data, and the ML model has been trained by adjusting weighting coefficients in a neural network to optimize a loss function that represents a distance metric between electrodynamic parameters predicted based on the train cycling data and electrodynamic parameters calculated from the corresponding probing waveform data.

In some aspects, the techniques described herein relate to a method of generating battery cell characterization data, the method including: inputting one or more scanning electron microscope (SEM) images of an electrode of the battery cell; analyzing the images to determine one or more degradation characteristics of the electrode; and outputting a score corresponding to a level of the determined electrode degradation characteristics.

In some aspects, the techniques described herein relate to a method, wherein the degradation characteristics of the electrode comprise one selected from a group consisting of plating, surface area, surface roughness, and dendrite growth.

In some aspects, the techniques described herein relate to a method, wherein analyzing the images comprises providing the images to a convolutional neural network (CNN) configured to detect image features related to degradation characteristics of the electrode.

In some aspects, the techniques described herein relate to a method, wherein the CNN is trained using a training set of manually scored SEM images.

In some aspects, the techniques described herein relate to a method including outputting at least one selected from a group consisting of an average of multiple scores, a standard deviation, a median score, a minimum score, and a maximum score from multiple SEM images of a single battery cell.

In some aspects, the techniques described herein relate to a computing apparatus including: a processor; and a memory storing instructions that, when executed by the processor, configure the apparatus to: apply both cycling data and electrodynamic parameters to a machine learning (ML) model, and, in response, outputting battery-performance information, wherein the cycling data is measured during charge and/or discharging of the battery.

In some aspects, the techniques described herein relate to a computing apparatus, wherein the ML model has been trained on training data that includes measured battery-performance information associated with corresponding training input data including training electrodynamic parameters and training cycling data, the training data being obtained from a corpus of historical measurements.

In some aspects, the techniques described herein relate to a computing apparatus, wherein the measured battery-performance information is a metric derived from measurements of respective batteries used to generate the corpus of historical measurements, and the metric selected from the group consisting of a state of charge (SOC) metric, a state of health (SOH) metric, and a remaining useful life (RUL) metric.

In some aspects, the techniques described herein relate to a computing apparatus, wherein the electrodynamic parameters are determined based on measurements when a probing waveform is applied to the battery.

In some aspects, the techniques described herein relate to a computing apparatus, wherein the electrodynamic parameters are based on one or more Lyapunov exponents corresponding to respective frequency ranges, one or more correlation dimensions, one or more sample entropies, one or more Hurst exponents, a fluctuation analysis, and/or a charge rate voltage slew.

In some aspects, the techniques described herein relate to a computing apparatus, wherein: the probing waveform periodically transitions from a charging period to a resting period and/or discharging period, during the charging period a voltage applied to the battery has a first pulse shape that on average is monotonically rising, and during the resting period and/or the discharging period the voltage applied to the battery has a second pulse shape that on average is monotonically falling.

In some aspects, the techniques described herein relate to a computing apparatus, wherein the first pulse shape and the selected pulse shape are selected to include frequencies within a predefined range based on a frequency dependance of an impedance of the battery.

In some aspects, the techniques described herein relate to a computing apparatus, wherein the corresponding training data further includes simulated battery-performance information generated by a physics-based model that predicts the simulated battery-performance information using the cycling data.

In some aspects, the techniques described herein relate to a computing apparatus, wherein the loss function includes a weighting term that determines a contribution of the first term relative to the second term, and a value of the weighting term is empirically derived to minimize non-physical predictions by the trained ML model.

In some aspects, the techniques described herein relate to a computing apparatus, wherein the physics-based model is selected from the group consisting of PYBAMM, COMSOL, DUALFOIL, FASTDEN, LIONSIMBA, and M-PET.

In some aspects, the techniques described herein relate to a computing apparatus, when executed by the processor, the instructions further configure the apparatus to: apply the cycling data to another ML model, and, in response, outputting the electrodynamic parameters that are applied as inputs to the ML model, wherein the another ML model has been trained using training data to predict the electrodynamic parameters, the training data including training cycling data associated with corresponding probing waveform data, and the another ML model having been trained by adjusting weighting coefficients in a neural network to optimize a loss function that represents a distance metric between electrodynamic parameters predicted based on the train cycling data and electrodynamic parameters calculated from the corresponding probing waveform data.

In some aspects, the techniques described herein relate to a computing apparatus, wherein the cycling data includes current measurements, voltage measurements, and/or temperature measurements.

In some aspects, the techniques described herein relate to a computing apparatus, wherein the cycling data is constant current constant voltage charging data in which, during charging a currant applied to the battery is maintained constant until a threshold voltage is reached and then a volage applied to the battery is maintained constant until charging is complete.

In some aspects, the techniques described herein relate to a computing apparatus, wherein the battery-performance information includes a state-of-charge (SOC) metric, a state-of-health (SOH) metric; and/or a remaining-useful-life (RUL) metric.

In some aspects, the techniques described herein relate to a computing apparatus, when executed by the processor, the instructions further configure the apparatus to: receive type information representing a type of the battery, and selecting the ML model from a plurality of ML models based on the type information, wherein the type information includes information representing a cathode material, an anode material, and/or an electrolyte.

In some aspects, the techniques described herein relate to a non-transitory computer-readable storage medium, the computer-readable storage medium including instructions that when executed by a computer, cause the computer to: apply both cycling data and electrodynamic parameters to a machine learning (ML) model, and, in response, outputting battery-performance information, wherein the cycling data is measured during charge and/or discharging of the battery.

In some aspects, the techniques described herein relate to a non-transitory computer-readable storage medium, wherein the ML model has been trained on training data that includes measured battery-performance information associated with corresponding training input data including training electrodynamic parameters and training cycling data, the training data being obtained from a corpus of historical measurements.

In some aspects, the techniques described herein relate to a non-transitory computer-readable storage medium, wherein the measured battery-performance information is a metric derived from measurements of respective batteries used to generate the corpus of historical measurements, and the metric selected from the group consisting of a state of charge (SOC) metric, a state of health (SOH) metric, and a remaining useful life (RUL) metric.

In some aspects, the techniques described herein relate to a non-transitory computer-readable storage medium, wherein: the ML model is trained by adjusting weights in a neural network to minimize a loss function that includes a first term and a second term, the first term representing a distance metric between the measured battery-performance information and the battery-performance information that is output from the ML model in response to applying the corresponding training input data, and the second term representing a distance metric between the simulated battery-performance information and the battery-performance information that is output from the ML model in response to applying the corresponding training input data.

In some aspects, the techniques described herein relate to a non-transitory computer-readable storage medium, wherein the electrodynamic parameters are determined based on measurements when a probing waveform is applied to the battery.

In some aspects, the techniques described herein relate to a non-transitory computer-readable storage medium, wherein the electrodynamic parameters are based on one or more Lyapunov exponents corresponding to respective frequency ranges, one or more correlation dimensions, one or more sample entropies, one or more Hurst exponents, a fluctuation analysis, and/or a charge rate voltage slew.

In some aspects, the techniques described herein relate to a non-transitory computer-readable storage medium, wherein the probing waveform periodically transitions from a charging period to a resting period and/or discharging period, during the charging period a voltage applied to the battery has a first pulse shape that on average is monotonically rising, and during the resting period and/or the discharging period the voltage applied to the battery has a second pulse shape that on average is monotonically falling.

In some aspects, the techniques described herein relate to a non-transitory computer-readable storage medium, wherein the first pulse shape and the selected pulse shape are selected to include frequencies within a predefined range based on a frequency dependance of an impedance of the battery.

In some aspects, the techniques described herein relate to a non-transitory computer-readable storage medium, wherein the corresponding training data further includes simulated battery-performance information generated by a physics-based model that predicts the simulated battery-performance information using the cycling data.

In some aspects, the techniques described herein relate to a non-transitory computer-readable storage medium, wherein the loss function includes a weighting term that determines a contribution of the first term relative to the second term, and a value of the weighting term is empirically derived to minimize non-physical predictions by the trained ML model.

In some aspects, the techniques described herein relate to a non-transitory computer-readable storage medium, wherein the physics-based model is selected from the group consisting of PYBAMM, COMSOL, DUALFOIL, FASTDEN, LIONSIMBA, and M-PET.

In some aspects, the techniques described herein relate to a non-transitory computer-readable storage medium, wherein, when executed by the computer, the instructions further cause the computer to: apply the cycling data to another ML model, and, in response, outputting the electrodynamic parameters that are applied as inputs to the ML model, wherein the another ML model has been trained using training data to predict the electrodynamic parameters, the training data including training cycling data associated with corresponding probing waveform data, and the another ML model having been trained by adjusting weighting coefficients in a neural network to optimize a loss function that represents a distance metric between electrodynamic parameters predicted based on the train cycling data and electrodynamic parameters calculated from the corresponding probing waveform data.

In some aspects, the techniques described herein relate to a non-transitory computer-readable storage medium, wherein the cycling data includes current measurements, voltage measurements, and/or temperature measurements.

In some aspects, the techniques described herein relate to a non-transitory computer-readable storage medium, wherein the cycling data is constant current constant voltage charging data in which, during charging a current applied to the battery is maintained constant until a threshold voltage is reached, and then a voltage applied to the battery is maintained constant until charging is complete.

In some aspects, the techniques described herein relate to a non-transitory computer-readable storage medium, wherein the battery-performance information includes a state-of-charge (SOC) metric, a state-of-health (SOH) metric; and/or a remaining-useful-life (RUL) metric.

In some aspects, the techniques described herein relate to a non-transitory computer-readable storage medium, wherein, when executed by the computer, the instructions further cause the computer to: receive type information representing a type of the battery, and selecting the ML model from a plurality of ML models based on the type information, wherein the type information includes information representing a cathode material, an anode material, and/or an electrolyte.

### Example Embodiments

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims.

The disclosed technology addresses the need in the art for predicting battery-performance information for a battery based on cycling data. For example, the systems and methods disclosed herein can use machine learning (ML) models to predict battery-performance information. Cycling data and electrodynamic parameters (EDPs) can be applied as inputs to the ML model, and, in response to the inputs, the ML model outputs the prediction of the battery-performance information. In some embodiments, cycling data may include dimensional cell measurements, temperature measurements, voltage measurements, current measurements, and values calculated based on dimensional, temperature, voltage, and/or current measurements.

Cycling data may further include battery cell characterization data obtained during cell tear-down processes. The characterization data may include estimations of plating, surface area, surface roughness, electrolyte condition, or other physical characteristics of the cell or components thereof. For example, scanning electron microscope (SEM) images may be taken during a tear-down process and may be used to characterize physical features of components of the battery cell (e.g., electrodes). In some embodiments, the SEM images may be characterized automatically using its machine learning algorithm in order to estimate battery degradation. The machine learning algorithm may be a convolutional neural network (CNN) trained using a set of SEM images representing multiple areas of electrodes (e.g., ends, center regions, edges of an anode or cathode) at various states of health and labeled by expert analytical chemists. The label may be a grade on a scale (e.g., from 1-10) where one end of the scale represents a new, non-degraded cell component and the opposite end represents a heavily degraded cell component at end of life. The CNN output may include automatic and accurate grading of SEM images for a battery cell, where weights within the CNN model are optimized to output grades matching the manually assigned labels. Output from the CNN model may include average grades, standard deviations, medians, min/max values, and other statistical information aggregated using multiple SEM images for a single battery cell. This information may be combined with other cycling data to correlate battery cell degradation with other direct measurements and/or calculated values.

According to certain non-limiting examples, the ML model is an artificial neural network (ANN) that is trained to predict the battery-performance information based on latent patterns and information in the cycling data and the EDPs. For example, training data (e.g., the cycling data and the EDPs that have been labeled using measured battery-performance information) can be used with a backpropagation method to train the ANN. According to certain non-limiting examples, the ML model can be a physics-informed neural network (PINN) that has been trained using both the above-described training data and battery-performance information predicted by a physics-based model of battery performance (e.g., PyBAMM).

Examples of battery-performance information can include, but are not limited to, the remaining useful life (RUL), state of health (SOH), and/or state of charge (SOC) for a battery based on cycling data and electrodynamic parameters (EDPs) that are generated either by calculating the EDPs using probing waveform data or by predicting the EDPs from cycling data.

As used herein, the term “battery performance” refers the battery health, the capacity for the battery to perform its functions now, and/or the capacity for the battery to perform these functions in the future (e.g., how much electrical energy is storied in the battery; how well does the battery store electrical energy, discharge electrical energy into a load, and is charged with electrical energy; and/or how will the battery degrade in these functions). Further, as used herein, the term “battery-performance information” refers to health information about the battery and/or performance metrics for the battery (e.g., remaining useful life (RUL), state of health (SOH), and/or state of charge (SOC)).

The remaining useful life (RUL) metric is an estimation of when the battery will reach its end-of-life (EOL). This occurs when the battery capacity decreases below a predefined threshold and should be replaced. For example, as the battery approaches its EOL, its capacity can decrease rapidly, and the battery can be prone to failure, which can affect the operation of equipment that depends on the battery, possibly resulting in safety issues. The change of battery capacity correlates with the degradation of the battery during the charge-discharge cycle. Thus, latent patterns in cycling data can be used by a machine learning (ML) model to predict battery performance degradation and to predict the RUL of batteries.

Similarly, a state of health (SOH) metric can correlate with the capacity of the battery to hold and deliver electrical energy to a load. As discussed above, the change of battery capacity correlates with the degradation of the battery during the charge-discharge cycle. Thus, latent patterns in cycling data can be used by a machine learning (ML) model to predict an SOH metric. For example, with the increase of battery charging and discharging times and the accumulation of sheltering time, the battery health status gradually deteriorates. Further, the battery's power and capacity can show varying degrees of attenuation, the battery capacity decreases, and the internal resistance increases. The capacity of the battery and/or the internal resistance can be used to define the SOH metric, for example. The state of charge (SOC) metric can be based on the ratio of the electrical power or charge stored in the battery relative to the present storage capacity of the battery.

According to certain non-limiting examples, lithium-ion batteries are widely used in electric vehicles because of their advantages of high energy density, low self-discharge, long useful life, and green environmental protection. On the one hand, after a long time of use, lithium batteries will age and decline in capacity, which can cause machine failure. On the other hand, replacing the battery too early can be inefficient, expensive, and wasteful of battery resources. Accurately predicting the RUL of lithium-ion batteries can mitigate these issues because accurate prediction can both reduce the likelihood of the occurrence of accidents caused by battery aging and also reduce the waste caused by premature battery replacement. Aspects of the present disclosure can be used to generate and control charge and discharge parameters thereby optimizing various possible attributes, alone or in combination by balancing between different attributes, including charge time, battery capacity and battery life, among others.

Aspects of the present disclosure involve a system including hardware and/or software for predicting the battery-performance information of a battery. These predictions benefit from using electrodynamic parameters that can be calculated using complex characterization parameters or mathematical functions applied to electrical measurements. In some embodiments, the electrical measurements are taken from an electrochemical system (e.g., a battery cell or battery pack). In some embodiments, multiple co-processor blocks may be used to perform computation many times faster than a normal CPU or graphics processing unit (GPU). In some embodiments, a CPU may offload computations to purpose-built hardware co-processor blocks (e.g., a single or multiple copies of the co-processor blocks).

As used herein, the term “battery” can be used in various ways and may refer to an individual cell having an anode and cathode separated by an electrolyte. Additionally or alternatively, the term “battery” can refer to a collection of such cells connected in various arrangements (e.g., in parallel or series). Further, the terms “charging” and “recharging” are used synonymously herein. A battery or battery cell is a form of electrochemical device. Batteries often include repeating units of sources of a countercharge and first electrode layers separated by an ionically conductive barrier, often a liquid or polymer membrane saturated with an electrolyte but may also be a solid electrolyte. The battery layers are often made to be thin so multiple units can occupy the volume of the battery, increasing the voltage/power of the battery with each stacked unit. Although many examples are discussed herein as applicable to a battery, it should be appreciated that the systems and methods described may apply to many different types of batteries, ranging from an individual cell to batteries involving different possible interconnections of cells, such as cells coupled in parallel, series, and parallel and series. For example, the systems and methods discussed herein may apply to a battery pack comprising numerous cells arranged to provide a defined pack voltage, output current, and/or capacity. Moreover, the implementations discussed herein may apply to different types of electrochemical devices, such as various types of lithium batteries, including but not limited to lithium-metal and lithium-ion batteries, lead acid batteries, various types of nickel batteries, and solid-state batteries, to name a few. The various implementations discussed herein may also apply to different structural battery arrangements such as cylindrical cells, pouch cells, and prismatic cells. These implementations may also apply to any other electrochemical sensors or systems where an electric current, a voltage, or other related stimulus is applied to the system to measure properties of the materials.

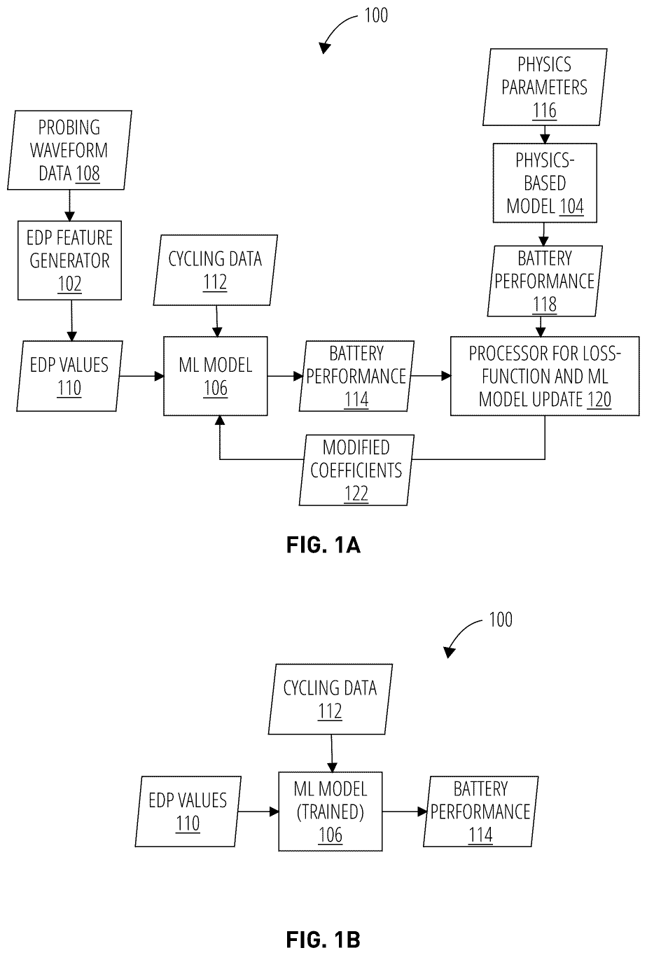

FIG. 1A and FIG. 1B illustrate block diagrams of system 100 for predicting battery performance. FIG. 1A illustrates system 100 configured for training a machine learning (ML) model (ML model 106) to predict battery performance, and FIG. 1B illustrates a configuration of system 100 when ML model 106 is being used to predict battery performance.

In FIG. 1A, ML model 106 receives two sets of inputs: EDP values 110 and cycling data 112, and in response to these inputs, ML model 106 generates battery performance 114. According to certain non-limiting examples, the EDP values 110 are calculated by EDP feature generator 102 using probing waveform data 108.

Processor for loss-function and ML model update 120 uses both battery performance 114 and battery performance 118, which are generated by physics-based model 104 based on physics parameters 116 to calculate a loss function, and, based on the loss function, processor for loss-function and ML model update 120 determines changes to the weighting coefficients in ML model 106. Modified coefficients 122 generated by processor for loss-function and ML model update 120 are used to iteratively update (i.e., train) ML model 106 until the loss function satisfies predefined convergence criteria, indicating that 106 is trained.

Thus, the configuration shown in FIG. 1A and FIG. 1B uses physics-based, battery-performance information (i.e., battery performance 118), which is calculated by physics-based model 104 using physics parameters 116, to train ML model 106. ML model 106 is trained by adjusting the weighting coefficients/parameters of ML model 106 to minimize a loss function that incorporates battery performance 118. The loss function can also be referred to as an error function, a cost function, an objective function, or an optimization function.

As discussed below, when ML model 106 is an artificial neural network (ANN), a backpropagation method can be used to adjust the weighting coefficients and thereby train ML model 106 to predict battery performance 114. The loss function can represent a difference between the predicted battery performance 114 and the measured battery performance, which is part of the labeled training data used to train ML model 106. Generally, labeled training data includes actual values for the desired output from the ML model (i.e., the label) associated with corresponding inputs to the ML model. Here, the outputs of ML model 106 are the battery-performance information (e.g., battery performance 114) for a given battery, and the inputs for ML model 106 are cycling data 112 and EDP values 110.

According to certain non-limiting examples, battery performance 118 is not used as an input to ML model 106, which is used to predict battery performance 114. Accordingly, battery performance 118 is used only during training as input to guide/constrain the training process to provide better predictions. For example, the physics-based battery-performance information can be used in the loss function to favor predictions of battery performance 114 that are more consistent with physics (e.g., disfavors non-physical results). The measured battery-performance information may be subject to noise or artifacts, and the physics-based battery-performance information can correct/counterbalance that noise or artifacts.

According to certain non-limiting examples, the loss function “L” can have the functional form

$$L = {L}_{physics} ( PyBaMM ) + {L}_{data ,}$$

wherein “L_{data}” is a term representing the difference between the predicted battery-performance information and the measured battery-performance information, and “L_{physics} (PyBaMM)” is a term representing the difference between the predicted battery-performance information and battery-performance information derived using the physics-based model.

Further, the data term “L_{data}” can be a distance measure that represents a difference between the measured battery-performance information (HE_{Meas,i}) and the predicted HE_{Pred,i}, where the index i is used to differentiate between multiple values in a vector representing the battery-performance information. According to certain non-limiting examples, the distance measure can be determined using an L^{P}-norm, such as:

$${L}_{data} = ( {\vec{HE}}_{Meas} , {\vec{HE}}_{PredMeas , i} ) {HE}_{Meas , i} = {( {\sum }_{i} {( {\vec{HE}}_{Meas , i} - {\vec{HE}}_{Pred , i} )}^{p} )}^{\frac{1}{p}}$$

For example, the Euclidean distance is simply the L²-norm. Other distance measures that can be used include the Cosine distance, Manhattan distance, Minkowski distance, etc.

FIG. 1B illustrates a configuration of system 100 when ML model 106 is being used to predict battery performance. According to certain non-limiting examples, EDP values 110 have been previously generated and stored such that only cycling data 112 is updated as the battery is used and ages.

For example, the battery can be used in a lightweight application (e.g., in a watch, on a small drone, a remote weather station, etc.), such that the battery is used in an environment, device, or apparatus that either lacks processing power to calculate EDP values 110 or where electrical power is scarce such that consuming electrical power to calculate EDP values 110 is disadvantageous. In this case, cycling data 112 might be readily obtained by monitoring the current, voltage, and temperature of the battery as it is being charged and discharged. However, generating EDP values 110 can be computationally more expensive and consume more electrical power than generating cycling data 112. Further, EDP values 110 can depend on using a specialized waveform (e.g., a probing waveform) to charge/discharge the battery, whereas cycling data 112 can be generated from measurements obtained using a more traditional charging scheme, e.g., continuous current continuous voltage (CCCV) charging. Thus, there can be various reasons why EDP values 110 are fixed values that are determined, e.g., during calibration of the battery at a factory before the battery is deployed in the field, whereas cycling data 112 is continuously updated as the battery is used and the battery undergoes an aging process.

Alternatively, EDP values 110 can be periodically updated. For example, at various intervals, probing waveform data 108 can be generated by applying a probing waveform to the battery, and EDP feature generator 102 can use the probing waveform data 108 to calculate updated EDP values 110 that are used by ML model 106. For example, heavyweight applications (e.g., batteries in electrical vehicles (EVs) or solar power storage for commercial or residential real estate) can have abundant power and processing capacity for generating EDP values 110. In heavyweight applications, the increased power consumption due to frequently updating EDP values 110 can be offset by the improvements to the system that result from improved predictions of the battery-performance information.

Whether EDP values 110 are fixed values or periodically updated values, cycling data 112 is continuously updated as the battery is cycled (e.g., charged and discharged), and the combination of EDP values 110 and cycling data 112 is applied to ML model 106 to predict battery performance 114. As shown in FIG. 1A, ML model 106 is trained using the outputs of physics-based model 104 for one of the terms in the loss function, but the outputs of physics-based model 104 are not used after ML model 106 has been trained. Thus, after training, ML model 106 uses as inputs EDP values 110 and cycling data 112.

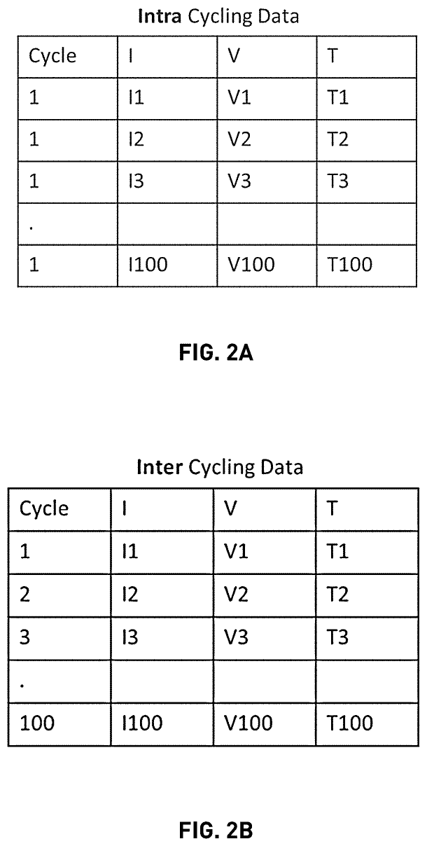

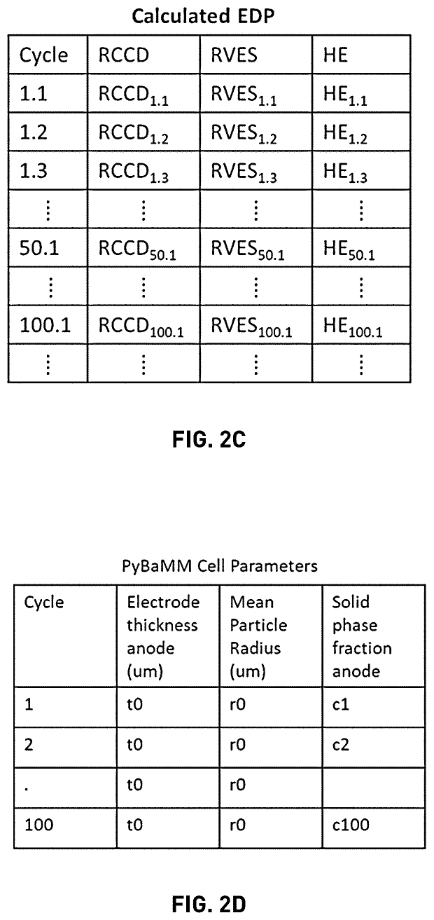

FIG. 2A and FIG. 2B show non-limiting examples of cycling data 112. For example, FIG. 2A shows intra-cycling data, which can be represented as a time series of measurements occurring during a single charging cycle. In FIG. 2A, the first column shows a label/index of the cycle. Here, the label/index is “1,” meaning this is the first cycle. The second column represents the respective values of current measurements (e.g., the label “I1” is a placeholder for a first current measurement, which can be a number representing a current measured in Amperes, for example). The third column represents the respective values of voltage measurements (e.g., the label “V1” is a placeholder for a first voltage measurement, which can be a number representing a voltage measured in volts at the terminal of a battery, for example). The fourth column represents the respective values of current measurements (e.g., the label “T1” is a placeholder for a first temperature measurement of the battery, which can be a number representing a temperature measured in degrees Centigrade or Fahrenheit, for example). The current, voltage, and temperature values can be averages during charging, discharging, or a combination thereof. The intra-cycling data can also include other values, such as time stamps. In FIG. 2A, each row represents a respective time at which the measurements were acquired.

FIG. 2B shows inter-cycling data, which can be the average of measurements of respective charging cycles. For example, the first column represents the label/index of the cycle. The label/index in the second row is “1,” meaning this is the first cycle. The label/index in the third row is “2,” meaning this row corresponds to measurements acquired during the second cycle, with the “3” in the fourth row indicating the third cycle, and so forth. In FIG. 2B, each row represents a respective cycle during which the measurements were acquired. Here, each row corresponds to a different cycle, and the measured values can represent average values during the cycle. Additionally or alternatively, the values of the inter-cycling data can represent an average over a portion of the respective charging cycles (e.g., during the charging or discharging portion of the charging cycle). Additionally or alternatively, the values of the inter-cycling data can represent a maximum, a minimum, a mode, or a mean of a measured value over all or a portion of the respective charging cycles.

In the non-limiting example shown in FIG. 2B, the second column represents an average current of a cycling period (e.g., the label “I1” is a placeholder for the average current measured during the first cycle, which can be a number in Amperes). The third column represents an average current over the cycling period (e.g., the label “V1” is a placeholder for the average voltage measured during the first cycle, which can be a number in volts). The fourth column represents the average temperature over the cycling period (e.g., the label “T1” is a placeholder for the average temperature measured during the first cycle, which can be in units of degrees Centigrade or Fahrenheit).

FIG. 2C illustrates a table representing a non-limiting example of electrodynamic parameters (EDPs). For example, EDP values 110 can be electrodynamic parameters that are metrics indicative of battery performance and battery aging, including, e.g., sample entropies, correlation dimensions, Lyapunov exponents (LEs), Hurst exponents (LEs), detrended fluctuation analysis (DFA) results, or charge rate voltage slew values. Further, EDP values 110 can be electrodynamic parameters described in U.S. Patent Application No. 63/540,924 titled “ELECTRODYNAMIC PARAMETERS” and filed on Sep. 27, 2023, which is incorporated herein by reference in its entirety. Further, EDP values 110 can be electrodynamic parameters as described in U.S. Patent Application No. 63/633,579 titled “METHODS, APPARATUS, AND SYTEMS FOR GENERATING COMPUTATIONAL ELECTRODYNAMIC PARAMETERS OF AN ELECTROCHEMICAL SYSTEM” and filed on Apr. 14, 2024, which is incorporated herein by reference in its entirety.

In FIG. 2C, the first column can be a label/index representing the cycle for each row. Each row can also be labeled with a time stamp or index representing a portion of the cycle. For example, the label/index “1.1” in the second row of the first column can represent the first period of the first cycle. The label/index “1.2” in the third row of the first column can represent the second period of the first cycle, with the label/index “1.3” in the fourth row of the first column representing the third period of the first cycle, and so forth.

In the second column, values are provided that represent an EDP in the specific form of Reduced-Complexity Correlation Dimension (RCCD) scores. The value labeled RCCD_{1.1}, which is in the second row of the second column, can represent the RCCD value during the first period of the first cycle. Similarly, the value labeled RCCD_{1.2}, which is in the third row of the second column, represents the RCCD value during the second period of the first cycle, and so forth.

In the third column, values are provided that represent an EDP in the specific form of Residual Vector Energy Separation Index (RVES) scores or exponents. The value labeled RVES_{1.1}, which is in the second row of the third column, can represent the RVES value during the first period of the first cycle. Similarly, the value labeled RVES_{1.2}, which is in the third row of the third column, represents the RVES value during the second period of the first cycle, and so forth.

In the fourth column, values are provided that represent an EDP in the specific form of Hurst Exponent (HE) scores or Dispersional Analysis-based Hurst Exponent (DAHE) scores. The value labeled HE_{1.1}, which is in the second row of the fourth column, can represent the HE value during the first period of the first cycle. Similarly, the value labeled HE_{1.2}, which is in the third row of the fourth column, represents the HE value during the second period of the first cycle, and so forth.

According to certain non-limiting examples, EDP values 110 can include Residual Vector Energy Separation (RVES) values/exponents. For example, the RVES values can be Lyapunov exponents (LEs) that are extracted from a probing waveform that is used for characterizing cell degradation. The LE can measure the sensitivity of a dynamical system to small perturbations. For example, the LE can be generated using the average rate of divergence or convergence of nearby trajectories in phase space (e.g., the space of all possible states of the system).

According to certain non-limiting examples, the LE can be a measure of the average rate at which nearby trajectories in phase space diverge or converge over time. When the LE is positive, trajectories diverge exponentially and the system is chaotic, whereas when the LE is negative, trajectories converge exponentially and the system is stable.

According to certain non-limiting examples, EDP values 110 can include Reduced Complexity Correlation Dimension (RCCD) values, which can represent how the number of pairs of points within a certain distance scale with the dimension of the space.

According to certain non-limiting examples, EDP values 110 can include Dynamic Sample Entropy (DSE) values, which can represent the sample entropy that is used to measure the amount of unpredictability of a time series. For example, the EDS values can be calculated similarly to calculations of correlation dimension and LE by constructing a trajectory/embedding matrix from the probing waveform.

According to certain non-limiting examples, EDP values 110 can include Dispersion Analysis based Hurst Exponent (DAHE) values/exponents. For example, the Hurst exponent can be a measure of the long-term memory of the probing waveform. The Hurst exponent can be calculated using rescaled range analysis. Further, the calculations of the Hurst exponent can include splitting the time series into shorter time series and then calculating the averaged rescale range for each shortened time series.

According to certain non-limiting examples, EDP values 110 can include Detrended Fluctuation Analysis (DFA) values, which are similar to Hurst exponents. These values can be generated using multifractal detrended fluctuation analysis. The DFA values can represent the degree of self-similarity or self-affinity, or degree of persistence, in the voltage and current signals (and related battery signals such as impedance or others). For example, these metrics can be used to quantify the nature of diffusion processes occurring in the battery. Diffusion can occur through and across the anode material (e.g., graphite), through interfaces such as the solid-electrolyte interphase (SEI) and cathode-electrolyte interphase (CEI), through the electrolyte, and/or through and across the cathode material. In Lithium-Ion Batteries, the anode and cathode can include layers of packed particles, and diffusion can be present, e.g., in the diffusion between these particles, as well as intercalation into the particles themselves.

According to certain non-limiting examples, EDP values 110 can include Charge Rate Voltage Slew (DIDVS) values.

FIG. 2D shows an example of physics parameters 116 that can be used by physics-based model 104 to calculate metrics representing battery performance 114. In this case, physics-based model 104 is a PyBAMM model.

According to certain non-limiting examples, physics parameters 116 can include electrode thickness anode (expressed in microns (μm)), mean Particle Radius (expressed in μm), solid phase fraction anode, etc.

According to certain non-limiting examples, physics parameters 116 can include electrode thickness, mean particle radius, solid phase fraction, liquid phase fraction, equilibrium potential, maximum Li⁺ concentration, initial Li⁺ concentration, reaction rate, etc.

The example of physics-based model 104 being a PyBAMM model is illustrative and non-limiting. Additional examples of physics modeling methods for batteries that can be used for physics-based model 104 can include, but are not limited to, COMSOL models, DUALFOIL models, FASTDEN models, LIONSIMBA models, and M-PET models.

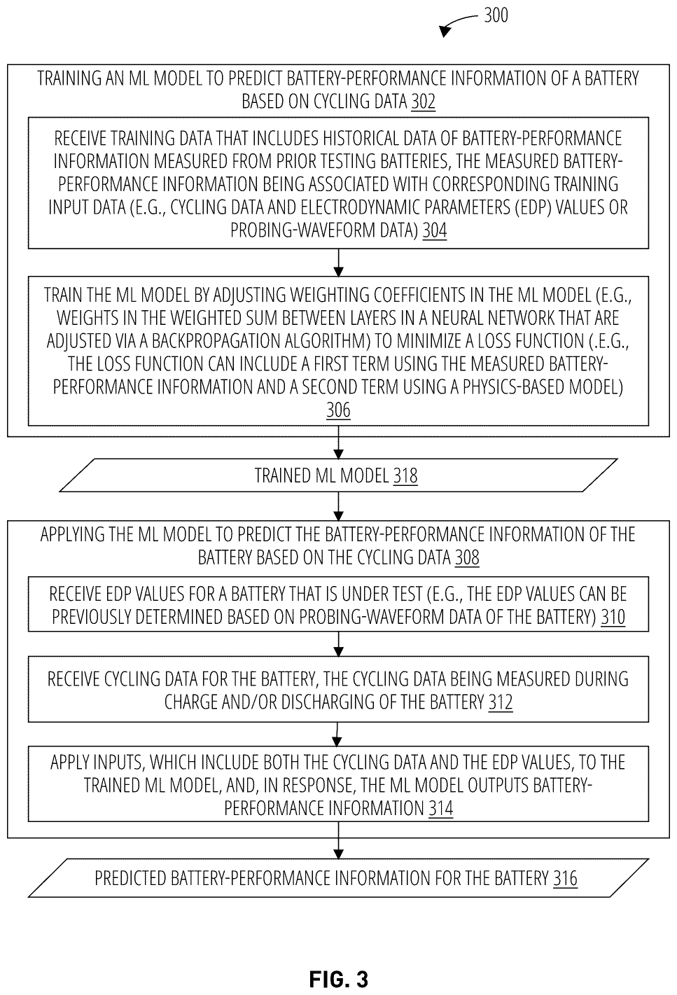

FIG. 3 illustrates an example method 300 for predicting battery-performance information for a battery using system 100, which is illustrated in FIG. 1A and FIG. 1B. Although the example method 300 depicts a particular sequence of operations, the sequence may be altered without departing from the scope of the present disclosure. For example, some of the operations depicted may be performed in parallel or in a different sequence that does not materially affect the function of the method 300. In other examples, different components of an example device or system that implements the method 300 may perform functions at substantially the same time or in a specific sequence.

According to some examples, process 302 of the method includes training a machine learning (ML) model (e.g., ML model 106) to predict battery-performance information of a battery (e.g., battery performance 114) based on cycling data (e.g., cycling data 112). Process 302 can use step 304 and step 306 to train the ML model, resulting in trained ML model 318.

According to some examples, in step 304, the method includes receiving training data that includes historical data of battery-performance information measured from prior testing of batteries. The measured battery-performance information is associated with corresponding training inputs (e.g., cycling data and electrodynamic parameters (EDP) values or probing-waveform data).

According to some examples, in step 306, the method includes training the ML model by adjusting weighting coefficients in the ML model (e.g., weights in the weighted sum between layers in a neural network that are adjusted via a backpropagation algorithm) to minimize a loss function (.e.g., the loss function can include a first term using the measured battery-performance information and a second term using a physics-based model).

According to certain non-limiting examples, the loss function “L” can have the functional form

$$L = {L}_{physics} ( PyBaMM ) + {L}_{data ,}$$

wherein “L_{data}” is a term representing the difference between the predicted battery-performance information and the measured battery-performance information, and “L_{physics} (PyBaMM)” is a term representing the difference between the predicted battery-performance information and battery-performance information derived using the physics-based model.

According to some examples, process 308 of the method applies the trained ML model 318 to predict the battery-performance information of the battery based on the cycling data. Process 308 can use step 310, step 312, and step 314 to use trained ML model 318 to generate predicted battery-performance information for the battery 316 based on the cycling data (e.g., cycling data 112).

According to some examples, in step 310, the method includes receiving EDP values for a battery that is under test (e.g., the EDP values can be previously determined based on probing-waveform data of the battery).

According to some examples, in step 312, the method includes receiving cycling data for the battery, the cycling data being measured during charging and/or discharging of the battery.

According to some examples, in step 314, the method includes applying inputs, which include both the cycling data and the EDP values, to the trained ML model, and, in response, the ML model outputs battery-performance information.

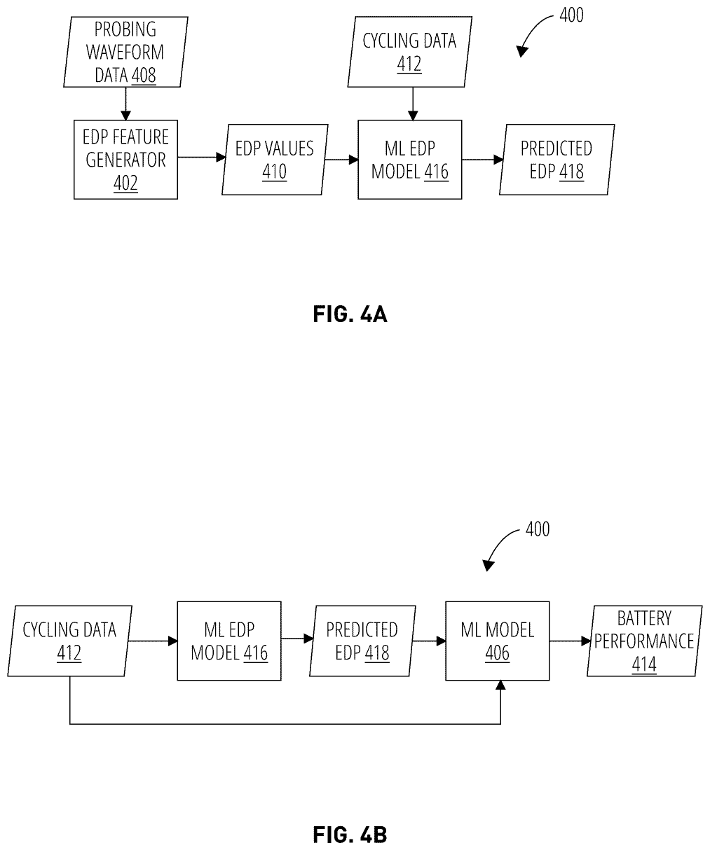

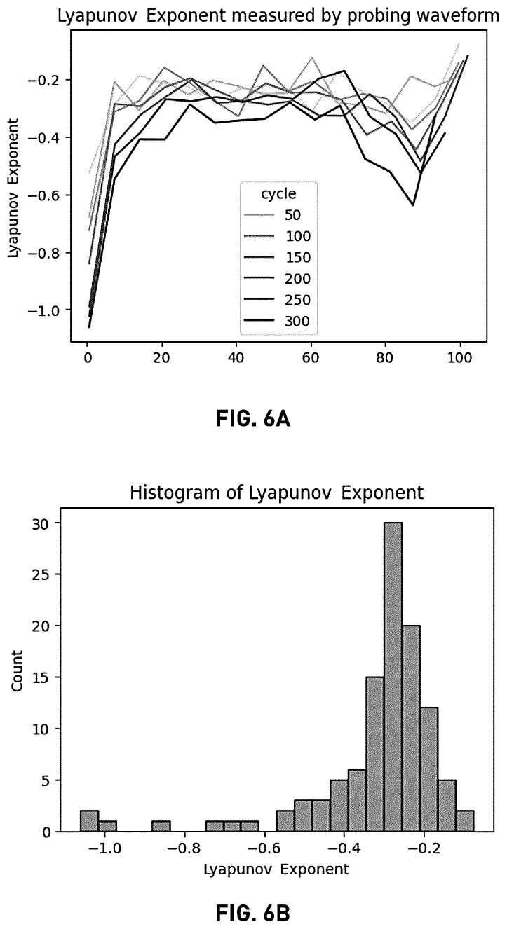

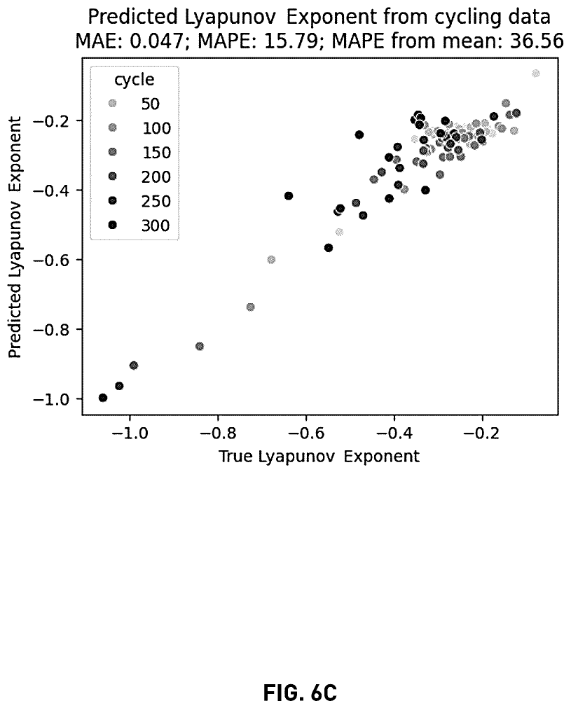

FIG. 4A and FIG. 6B illustrate system 400 using ML EDP model 416 and ML model 406 to predict battery performance 414 based on cycling data 412. FIG. 4A illustrates using system 400 to train ML EDP model 416 to generate predicted EDP 418, and FIG. 4B illustrates training and/or using ML model 406 to predict battery performance 414 based on cycling data 412.

In FIG. 4A, ML EDP model 416 receives two sets of inputs: EDP values 410 and cycling data 412. EDP values 410 are generated by applying probing waveform data 408 to EDP feature generator 402.

According to certain non-limiting examples, the EDP values 410 are calculated by EDP feature generator 402 using probing waveform data 408, as described above for system 100.

Further, the physics-based battery-performance information is calculated by physics-based model 104 using physics parameters 116. ML model 106 is then trained by adjusting the weighting coefficients/parameters of ML model 106 to minimize a loss function (also referred to as error function, cost function, objective function, or optimization function).

According to certain non-limiting examples, ML EDP model 416 can be an artificial neural network (ANN) that is trained using a backpropagation method can be used to adjust the weighting coefficients to minimize a loss function (or an error function or an objective function) that represents a difference between the EDP values 410 and predicted EDP 418. Thus, ML EDP model 416 learns innate patterns in cycling data 412 that correlate to values of EDP values 410, such that ML EDP model 416 outputs predicted EDP 418 that approximately match EDP values 410 in response to cycling data 412 being applied to ML EDP model 416.

FIG. 4B illustrates system 400 when is configured to predict battery performance 414 by applying cycling data 412 to ML model 406. After ML EDP model 416 has been trained, system 400 can be configured as illustrated in FIG. 4B to train ML model 406. While being trained, cycling data 412 is taken from a set of training data in which measured values for the battery performance are associated with cycling data 412, such that a loss function can be determined, wherein the loss function represents a difference between the measured battery performance and battery performance 414, which is generated by applying cycling data 412 and predicted EDP 418 to battery performance 414. For example, ML model 406 can be an artificial neural network (ANN) that is trained using a backpropagation method to adjust the weighting coefficients to minimize the loss function.

The configuration shown in FIG. 4B can also be used after ML model 406 and ML EDP model 416 have been trained to predict battery performance 414 from cycling data 412. First, 412 is applied to ML EDP model 416, which, in response to cycling data 412, outputs predicted EDP 418. Second, the combined inputs of predicted EDP 418 and cycling data 412 are applied to ML model 406, which, in response to the combined inputs, outputs battery performance 414.

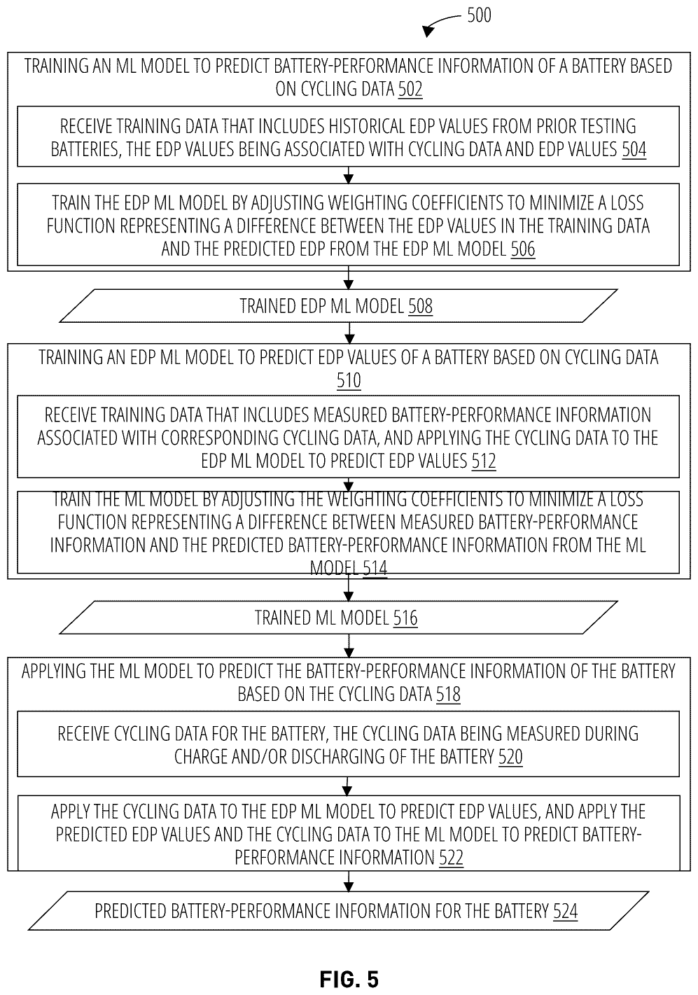

FIG. 5 illustrates an example method 500 for training and using ML model 406 and ML EDP model 416 to predict battery-performance information for a battery using system 400, which is illustrated in FIG. 4A and FIG. 4B. Although the example method 500 depicts a particular sequence of operations, the sequence may be altered without departing from the scope of the present disclosure. For example, some of the operations depicted may be performed in parallel or in a different sequence that does not materially affect the function of the method 500. In other examples, different components of an example device or system that implements the method 500 may perform functions at substantially the same time or in a specific sequence.

According to some examples, process 502 of the method includes training an EDP ML model (e.g., ML EDP model 416) to predict EDP values (e.g., ML EDP model 416) of a battery. Process 502 can use step 504 and step 506 to train the ML EDP model 416, resulting in trained EDP ML model 508.

According to some examples, in step 504, the method includes receiving training data that includes historical EDP values from prior testing batteries, the EDP values being associated with cycling data and EDP values.

According to some examples, in step 506, the method includes training the EDP ML model by adjusting weighting coefficients to minimize a loss function representing a difference between the EDP values in the training data and the predicted EDP from the EDP ML model at step 506.

According to some examples, process 510 of the method includes training an ML model to predict battery-performance information of a battery based on cycling data and predicted EDP values. Process 510 can use step 512 and step 514 to train an ML model (e.g., ML model 406), resulting in trained ML model 516.

According to some examples, in step 512, the method includes receiving training data that includes measured battery-performance information associated with corresponding cycling data, and applying the cycling data to the EDP ML model to predict EDP values.

According to some examples, in step 514, the method includes training the ML model by adjusting the weighting coefficients to minimize a loss function representing a difference between measured battery-performance information and the predicted battery-performance information from the ML model.

According to some examples, the method includes applying the ML model to predict the battery-performance information of the battery based on the cycling data at process 518. Process 518 uses step 520 and step 522 to predict the battery-performance information of the battery based on the cycling data.

According to some examples, in step 520, the method includes receiving cycling data for the battery, the cycling data being measured during charge and/or discharging of the battery.

According to some examples, in step 522, the method includes applying the cycling data to the EDP ML model to predict EDP values and applying the predicted EDP values and the cycling data to the ML model to predict battery-performance information.

FIG. 6A shows an example of LE for a battery at increments of 50 cycles (e.g., 50, 100, . . . , 300 cycles). The LE values are shown along the vertical axis, and the state of charge (SOC) values are shown along the horizontal axis.

FIG. 6B shows a histogram of the LE values. These LE values are examples of EDP values 410 that are used to train ML EDP model 416 to generate predicted EDP 418.

FIG. 6C shows results for predicting EDP values based on cycling data. For example, FIG. 6C shows the agreement between the LE values of EDP values 410 (horizontal axis) and the LE values of predicted EDP 418 (vertical axis), which were predicted by applying cycling data 412 to ML EDP model 416. It can be observed in FIG. 6C that the LE values of EDP values 410 are in good agreement with the LE values of predicted EDP 418.

The mean absolute percentage error (MAPE) when comparing the true LE values (horizontal axis) and the predicted LE values (vertical axis) is 15.79, whereas the MAPE is 36.56 when using the mean value of the LE values in the training data set as the predicted LE value.

The mean absolute percentage error (MAPE), also known as mean absolute percentage deviation (MAPD), is a measure of prediction accuracy of a forecasting method in statistics. It usually expresses the accuracy as a ratio defined by the formula:

$$MAPE = 100 \frac{1}{n} {\sum }_{t = 1}^{n} \vert \frac{{A}_{t} - {F}_{t}}{{A}_{t}} \vert ,$$

wherein Aₜ is the actual value and Fₜ is the forecast value. Their difference is divided by the actual value Aₜ. The absolute value of this ratio is summed for every forecasted point in time and divided by the number of fitted points n.

In the absence of additional information, the best guess for the LE value can be to choose the mean of previously observed LE values (e.g., the mean LE value of the training data set). Thus, the 36.56 MAPE can be viewed as a baseline, and additional information can be used to improve the MAPE. Here, there is additional information, which improves the estimation of the LE values, resulting in an MAPE of 15.79, which is less than half of the MAPE of 36.56 (i.e., the baseline).

A similar process can be used for the other predicted EDPs 418 (e.g., correlation dimension, sample entropy, and Hurst exponent (HE)). In Table 1 below, the model MAPE (i.e., MAPE between model-predicted EDPs 418 and the actual EDPs) is contrasted with the baseline MAPE (i.e., MAPE between the mean EDP of the training set and the actual EDPs). That is, Table 1 shows the Model MAPE in the second column, which can be contrasted with the baseline MAPE EDP in the third column. For each of the EDP values, the predicted EDPs provide over a 50% improvement over the baseline, except for the HE predictions. The EDP values in Table 1 include (i) the correlation dimension (second row), (ii) the sample entropy (third row), (iii) the Lyapunov exponent (fourth row), and (iv) the Hurst exponent (fifth row).

TABLE 1
Mean absolute percentage error (MAPE) of EDP values in
the training data (second column) with EDP values that
are predicted using a trained ML model (third column).

| EDP | Model MAPE | Baseline MAPE |
|---|---|---|
| Correlation | 8.39 | 22.03 |
| Dimension | | |
| Sample | 3.59 | 7.23 |
| Entropy | | |
| Lyapunov | 15.79 | 36.56 |
| Exponent | | |
| Hurst | 4.24 | 4.82 |
| Exponent | | |

Predicting the EDP values based on cycling data can be simpler and less computationally intensive compared to traditional methods of calculating the EDP values. Traditional methods of calculating the EDP values can be computationally intensive (e.g., consume significant computational resources and energy) and can depend on specialized probing waveforms. Many battery applications (especially lightweight applications) may not have access to the specialized probing waveforms and/or computational resources that are used to calculate the EDP values using traditional methods. To overcome this challenge, the EDP values can be determined during calibrations (e.g., at the factory when the product is manufactured or repaired), and then changes to the EDP values can be predicted based on the cycling data. Additionally or alternatively, the EDP values can be predicted based on the cycling data. In a hybrid scenario, the EDP values can be calculated at predefined intervals using traditional methods of calculating the EDP value, and, in the interim between the applications of the traditional methods, changes to the EDP value can be predicted based on the cycling data.

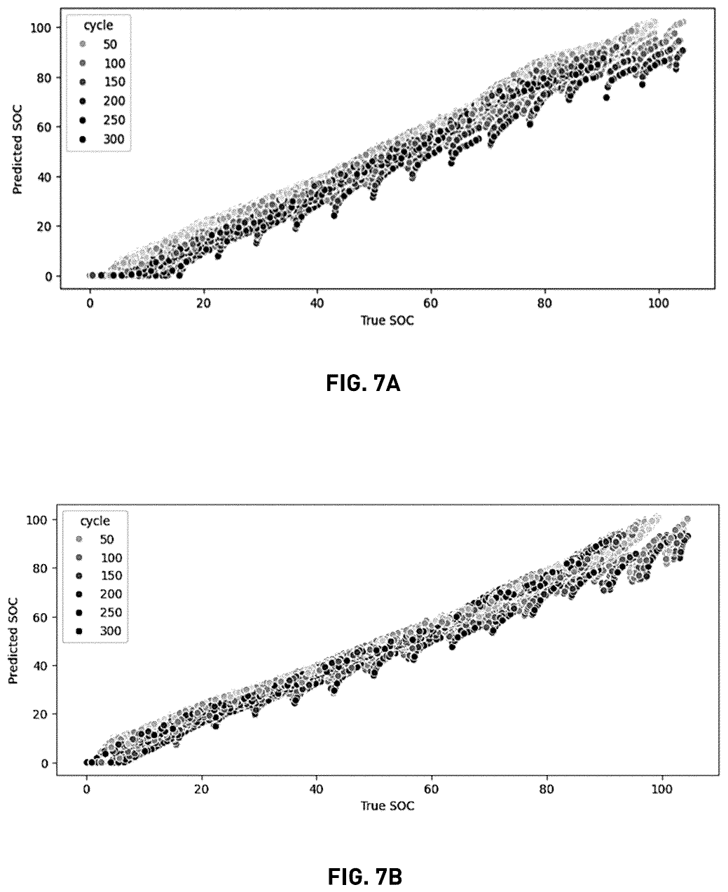

FIG. 7A shows a non-limiting example of battery performance 414 that is predicted by an ML model that uses only cycling data 412 without using the EDP values. FIG. 7A shows the predicted state of charge (SOC) (vertical axis) as a function of the true SOC (horizontal axis) for cycles 50, 100, 150, 200, 250, and 300. The MAPE for the shown results is 14.53.

FIG. 7B shows a non-limiting example of battery performance 414 that is predicted using system 400, as illustrated in FIG. 4B. More particularly, FIG. 7B shows the predicted state of charge (SOC) (vertical axis) as a function of the true SOC (horizontal axis) for cycles 50, 100, 150, 200, 250, and 300. Here, the predicted SOC was predicted using both the cycling data and the predicted EDP 418. The MAPE for the shown results is 9.09. Comparing the 14.53 MAPE (for FIG. 7A) of the SOC predicted without using the EDP values with the 9.09 MAPE (for FIG. 7B) of the SOC predicted using the predicted EDP values demonstrates that using the predicted EDP values can improve the predictions of the SOC specifically, and likely indicates that using the predicted EDP values can improve the prediction of battery-performance information more generally.

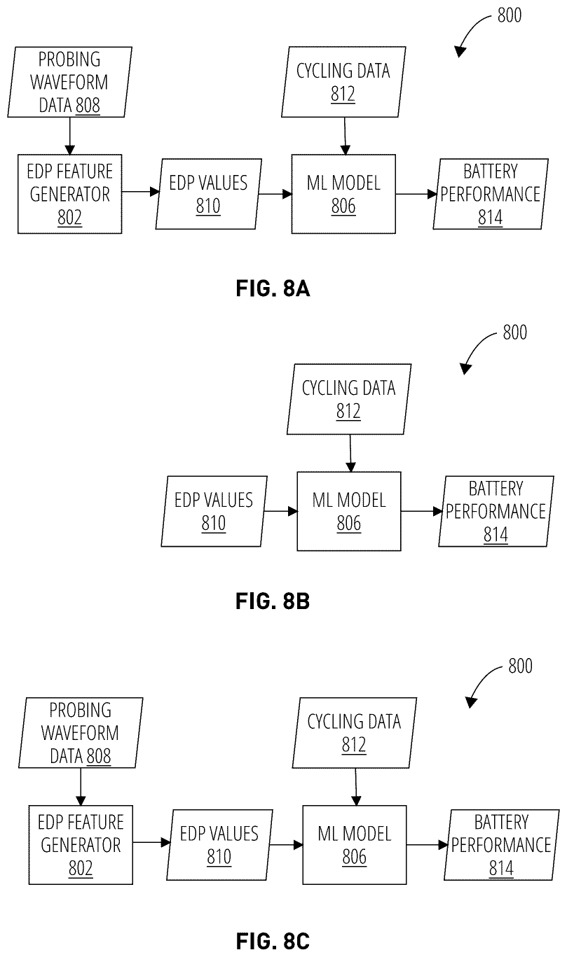

FIG. 8A, FIG. 8B, and FIG. 8C illustrate block diagrams of system 800 for predicting battery performance. In FIG. 8A, ML model 806 is trained to predict battery performance 814 based on inputs of cycling data 812 and EDP values 810. EDP values 810 can be generated by applying probing waveform data 808 to EDP feature generator 802.

In the configuration of system 800 shown in FIG. 8A, ML model 406 is trained using training data. For example, the training data can include cycling data 812 that is associated/labeled by measured values for the battery performance, such that a loss function can be determined, wherein the loss function represents a difference between the measured battery performance and battery performance 814, which is generated by applying cycling data 812 and EDP values 810 to ML model 806 to generate battery performance 814. For example, ML model 806 can be an artificial neural network (ANN) trained using a backpropagation method to adjust the weighting coefficients to minimize the loss function.

In FIG. 8B, EDP values 810 and cycling data 812 are applied to ML model 806 to predict battery performance 814. FIG. 8B illustrates a non-limiting example in which EDP values 810 are fixed. For example, this can occur in a scenario where the battery is deployed in an application where it is not practical to obtain probing waveform data 808. Thus, EDP values 810 can, e.g., be determined during an initial calibration at the factory and recorded in a non-volatile memory before deploying the battery in the application.

FIG. 8C illustrates a non-limiting example in which EDP values 810 can be updated. For example, EDP values 810 can be periodically updated at fixed intervals, or EDP values 810 can be updated when certain conditions trigger a recalibration of EDP values 810 (e.g., when changes in cycling data 812 indicate one or more statistically significant deviations in performance or aging). For example, this can occur in a scenario where the battery is deployed in an application having sufficient processing power to perform the calculations to generate EDP values 810, and where the additional power consumed by such processing does not present a significant burden to the total power budget. For example, the calculations for determining EDP values 810 might be a small percentage of the total power budget for an electric vehicle (EV), but might be a large percentage of the total power budget for wearable technology (e.g., smart eyeglasses). If this is the case, the configuration in FIG. 8C might be used in heavyweight applications (e.g., EV applications, renewable energy (solar, wind, etc.) charging applications, electrical grid applications, etc.), whereas the configuration in FIG. 8B might be used in lightweight applications (e.g., wearable-technology applications, power tool applications, small mobile devices such as an electric scooter, etc.).

Battery performance 814 can be sent to a computing device (e.g., a battery management system or controller) that is configured to use battery performance to determine one or more actions to be performed on or with respect to the battery. For example, the one or more actions performed on the battery can include replacing the battery at a time determined based on battery performance 814, an accident prevention action, a battery management action, managing a charging cycle, preventing overcharging, and/or preventing undercharging the battery.

According to certain non-limiting examples, battery performance 814 can include or be used to determine a state of charge (SOC) metric, a state of health (SOH) metric, and/or a remaining useful life (RUL) metric. A battery-management system (BMS) or higher-level controller can use SOC estimates to dynamically predict available charge and remaining driving or runtime. For example, in electric vehicles, accurate SOC enables reliable range projection and aids in managing regenerative braking and charge scheduling. Likewise, SOH estimates feed into maintenance decisions-once detected below an operational threshold (e.g., 80% capacity), the system can schedule service or derate power to prolong battery life. RUL forecasts inform long-term lifecycle planning: a fleet manager can preemptively replace units nearing end-of-life before failure or underperformance. These are examples of actions that can be determined based on battery performance 814, including replacement timing, charge cycle management, and safety precaution protocols.

Additionally or alternatively, a system receiving SOH and RUL can detect unusual degradation trends—such as accelerated capacity fade—triggering accident prevention actions like thermal protections, load shedding, or safe shutdowns before safety-critical failures. This is especially relevant in large-scale EV fleets and renewable energy storage, where early detection can prevent catastrophic battery failure. These are examples of actions that can be determined based on battery performance 814, including accident prevention action.

According to certain non-limiting examples, in stationary energy storage systems (e.g., solar-plus-storage or grid scale), SOC helps optimize charging/discharging to balance demand, minimize wear, and align with renewable production peaks. SOH and RUL guide battery lifecycle and replacement planning, ensuring sustainability and reliability across energy assets. The system can automatically schedule maintenance or reallocate cells nearing end-of-life for lower-demand uses.

According to certain non-limiting examples, during cell production and testing, SOC/SOH/RUL metrics derived from rapid cycling data and EDP-informed ML predictions enable non-destructive quality control of cells in real time. Defective or underperforming units are flagged before final assembly or deployment, reducing waste and improving yield. In R&D, designers can evaluate new chemistries or architectures via predicted lifetime profiles rather than lengthy aging.

For remote or resource-constrained devices (e.g., sensor nodes, drones), onboard computation of SOC, SOH, RUL enables self-managing battery health. The system can initiate sleep cycles, schedule maintenance, or adapt power consumption based on remaining capacity or predicted life. These are examples of battery management actions and charge/discharge management.

At the system level, combining SOC, SOH, and RUL empowers predictive algorithms to optimize battery usage policies, such as limiting charge depth to prolong life or adjusting operating conditions to avoid accelerated degradation. Charge rate, depth-of-discharge limits, or thermal controls can be adapted in real time, improving both safety and longevity.

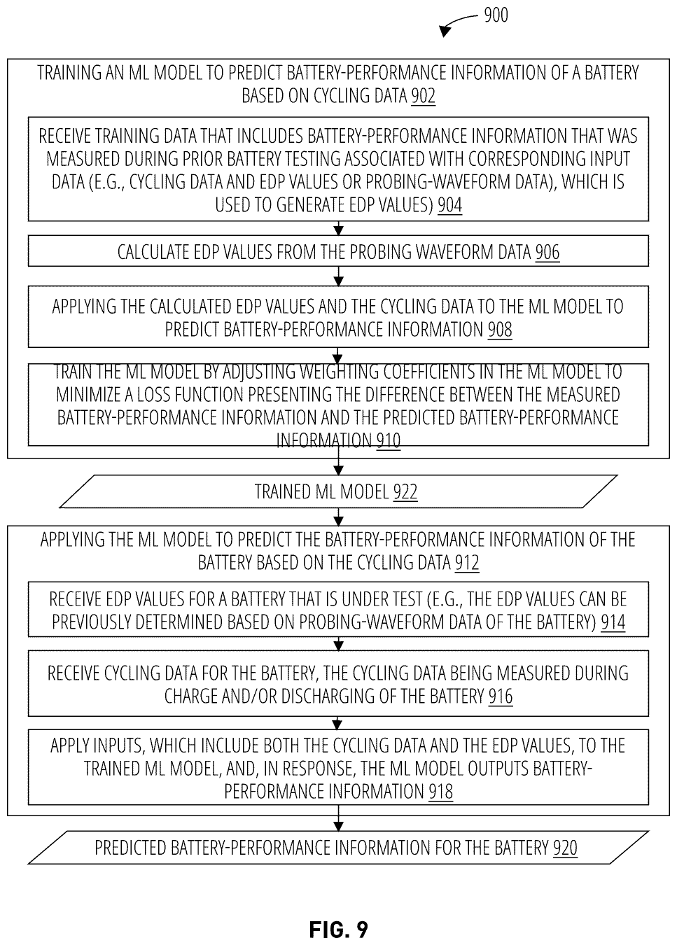

FIG. 9 illustrates an example method 900 for predicting battery-performance information for a battery using system 800, which is illustrated in FIG. 8A, FIG. 8B, and FIG. 8C. Although the example method 900 depicts a particular sequence of operations, the sequence may be altered without departing from the scope of the present disclosure. For example, some of the operations depicted may be performed in parallel or in a different sequence that does not materially affect the function of the method 900. In other examples, different components of an example device or system that implements the method 900 may perform functions at substantially the same time or in a specific sequence.

According to some examples, process 902 of the method includes training an ML model to predict battery-performance information (e.g., battery performance 814) of a battery based on cycling data (e.g., cycling data 812). Process 902 can use step 904, step 906, step 908, and step 910 to train the ML model, resulting in trained ML model 922 (e.g., ML model 806).

According to some examples, in step 904, the method includes receiving training data that includes battery-performance information that was measured during prior battery testing associated with corresponding input data (e.g., cycling data and EDP values or probing-waveform data), which is used to generate EDP values.

According to some examples, in step 906, the method includes calculating EDP values from the probing waveform data.

According to some examples, in step 908, the method includes applying the calculated EDP values and the cycling data to the ML model to predict battery-performance information.

According to some examples, in step 910, the method includes training the ML model by adjusting weighting coefficients in the ML model to minimize a loss function presenting the difference between the measured battery-performance information and the predicted battery-performance information.

According to some examples, process 912 of the method includes applying the ML model to predict the battery-performance information of the battery based on the cycling data. Process 912 can use step 914, step 916, and step 1018 to use trained ML model 922 to generate predicted battery-performance information for the battery 920.

According to some examples, in step 914, the method includes receiving EDP values for a battery that is under test (e.g., the EDP values can be previously determined based on probing-waveform data of the battery). That is, the EDP values can be obtained either as shown in FIG. 8B or in FIG. 8C.

According to some examples, in step 916, the method includes receiving cycling data for the battery, the cycling data being measured during charge and/or discharging of the battery.

According to some examples, in step 918, the method includes applying inputs, which include both the cycling data and the EDP values, to the trained ML model, and, in response, the ML model outputs battery-performance information.

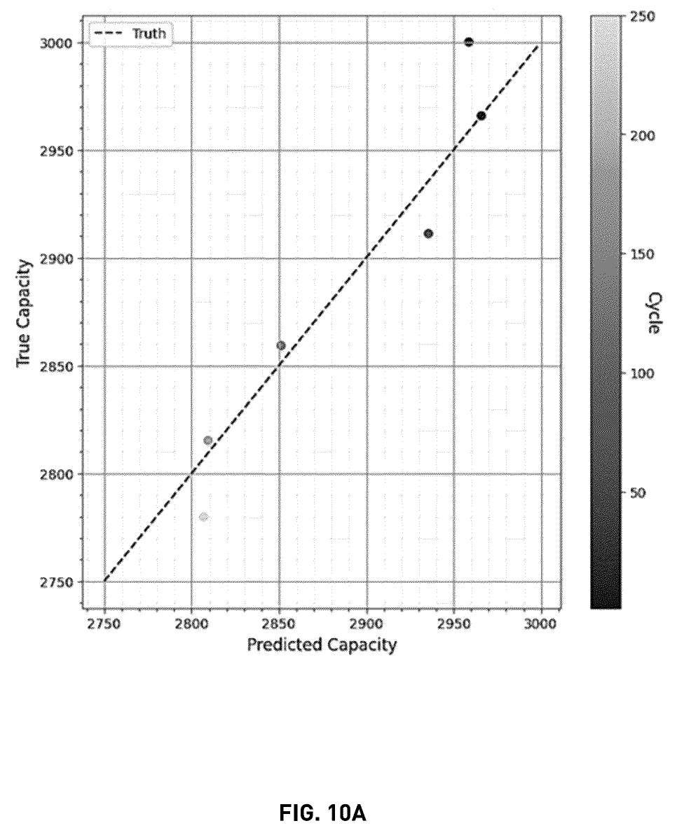

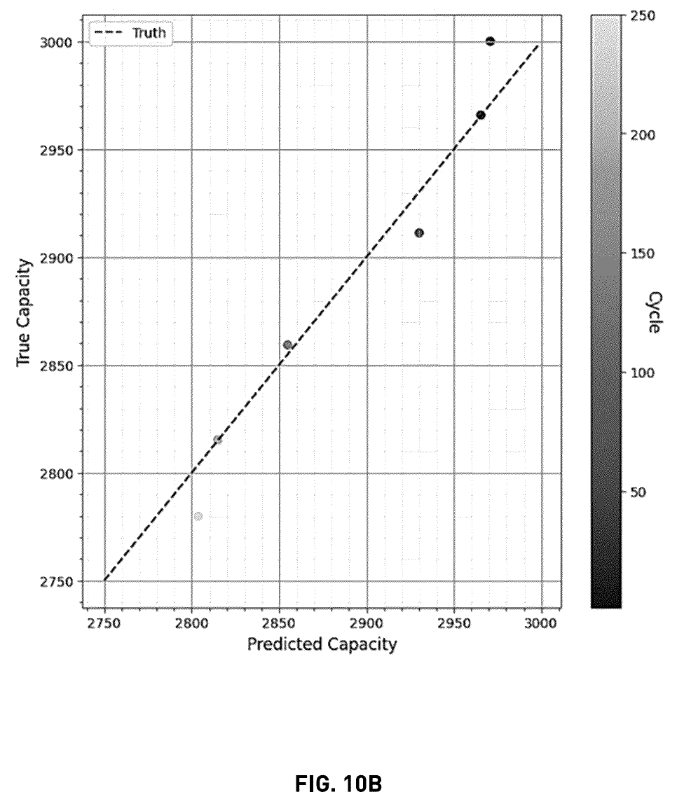

FIG. 10A shows a non-limiting example of battery performance that is predicted by an ML model that uses only cycling data. More particularly, FIG. 10A shows the predicted capacity as the state of health (SOH) (horizontal axis) as a function of the true capacity as the SOH (vertical axis) for cycles 50, 100, 150, 200, 250, and 300. The mean absolute error (MAE) for the shown results is 17.8. The dashed line shows the result in which the predicted capacity equals the true capacity.

The mean absolute error (MAE) is a measure of errors between paired observations expressing the same phenomenon. Examples of Y versus X include comparisons of predicted versus observed, subsequent time versus initial time, and one technique of measurement versus an alternative technique of measurement. MAE is calculated as the sum of absolute errors (i.e., the Manhattan distance) divided by the sample size:

$$MAE = \frac{{\sum }_{i = 1}^{n} \vert {y}_{i} - {x}_{i} \vert}{n} = \frac{{\sum }_{i = 1}^{n} \vert {e}_{i} \vert}{n} .$$

The MAE is an arithmetic average of the absolute errors |eᵢ|=|yᵢ−xᵢ|, wherein yᵢ is the prediction and xᵢ the true value.

FIG. 10B a non-limiting example of battery performance 814 that is predicted using system 400, as illustrated in FIG. 8C. More particularly, FIG. 10B shows the predicted capacity as the state of health (SOH) (horizontal axis) as a function of the true capacity as the SOH (vertical axis) for cycles 50, 100, 150, 200, 250, and 300. Here, the predicted SOH was predicted using both the cycling data 812 and EDP values 810. Here, the EDO values used as inputs to the ML model are LE, HE, Sample Entropy, and Correlation Dimension. The mean absolute error (MAE) for the shown results is 12.8, resulting in an improvement relative to the case in FIG. 10A using only cycling data.

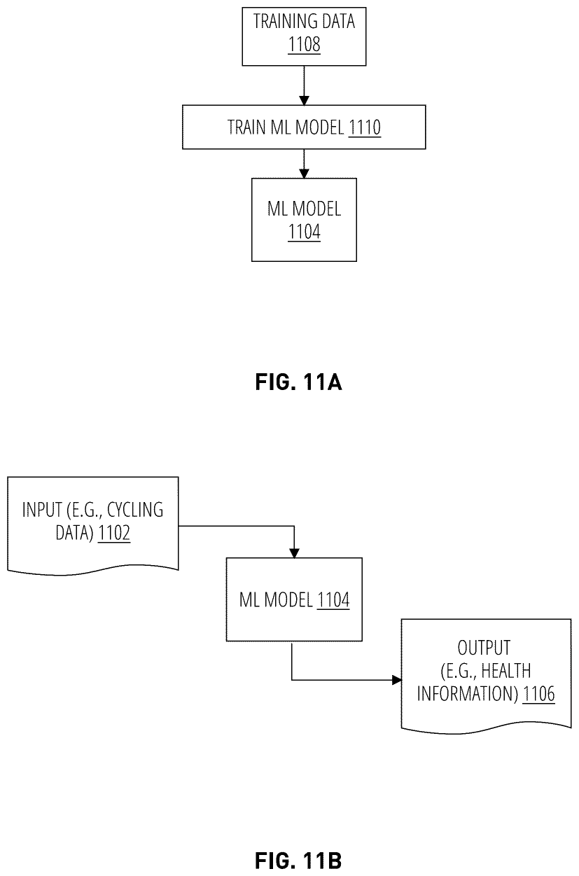

FIG. 11A illustrates an example of training an ML model 1104 (e.g., examples of ML models include, bat are not limited to ML model 106, ML model 406, ML EDP model 416, and ML model 806). In step 1110, training data input 1102 is applied to train the ML model 1104. For example, the ML model 1104 can be an artificial neural network (ANN) that is trained via supervised learning using a backpropagation technique in which ML model 1104 is trained by adjusting the weighting parameters connecting nodes between respective layers of the ANN.

In supervised learning, the training data 1108 is applied as an input to the ML model 1104, and an error/loss function is generated by comparing the output from the ML model 1104 with labels associated with the inputs. For example, the labels can be the ground truth. For training ML model 106, ML model 406, and ML model 806, the labels can be measured battery-performance information (e.g., experimentally determined SOH, SOC, or RUL values) that are associated with the cycling data. For training ML EDP model 416, the labels can be the experimentally determined EDP values that are associated with the cycling data. The coefficients of the ML model 1104 are iteratively updated to reduce an error/loss function.

The value of the error/loss function decreases as outputs from the ML model 1104 increasingly approximate the labels. In other words, ANN infers the mapping implied by the training data, and the error/loss function produces an error value related to the mismatch between the labels 504 and the outputs from the prediction engine 104 that are produced as a result of applying the training inputs (e.g., the cycling data) to the ML model 1104.

For example, in certain implementations, the cost function can use the mean-squared error to minimize the average squared error. In the case of a multilayer perceptrons (MLP) neural network, the backpropagation algorithm can be used for training the network by minimizing the mean-squared-error-based cost function using a gradient descent method.

Training a neural network model essentially means selecting one model from the set of allowed models (or, in a Bayesian framework, determining a distribution over the set of allowed models) that minimizes the cost criterion (i.e., the error value calculated using the error/loss function). Generally, the ANN can be trained using any of numerous algorithms for training neural network models (e.g., by applying optimization theory and statistical estimation).

For example, the optimization method used in training artificial neural networks can use some form of gradient descent, using backpropagation to compute the actual gradients. This is done by taking the derivative of the cost function with respect to the network parameters and then changing those parameters in a gradient-related direction. The backpropagation training algorithm can be: a steepest descent method (e.g., with variable learning rate, with variable learning rate and momentum, and resilient backpropagation), a quasi-Newton method (e.g., Broyden-Fletcher-Goldfarb-Shannon, one step secant, and Levenberg-Marquardt), or a conjugate gradient method (e.g., Fletcher-Reeves update, Polak-Ribiére update, Powell-Beale restart, and scaled conjugate gradient). Additionally, evolutionary methods, such as gene expression programming, simulated annealing, expectation-maximization, non-parametric methods and particle swarm optimization, can also be used for training the ML model 1104.

The training 1110 of the ML model 1104 can also include various techniques to prevent overfitting to the training data 1108 and for validating the trained ML model 1104. For example, bootstrapping and random sampling of the training data 1108 can be used during training.

In addition to supervised learning used to initially train the ML model 1104, the ML model 1104 can be continuously trained while being used by using reinforcement learning.

Further, other machine learning (ML) algorithms can be used for the ML model 1104, and the ML model 1104 is not limited to being an ANN. For example, there are many machine-learning models, and the ML model 1104 can be based on machine learning systems that include generative adversarial networks (GANs) that are trained, for example, using pairs of network measurements and their corresponding optimized configurations.

As understood by those of skill in the art, machine-learning based classification techniques can vary depending on the desired implementation. For example, machine-learning classification schemes can utilize one or more of the following, alone or in combination: hidden Markov models, recurrent neural networks (RNNs), convolutional neural networks (CNNs); Deep Learning networks, Bayesian symbolic methods, general adversarial networks (GANs), support vector machines, image registration methods, and/or applicable rule-based systems. Where regression algorithms are used, they can include but are not limited to: a Stochastic Gradient Descent Regressors, and/or Passive Aggressive Regressors, etc.

Machine learning classification models can also be based on clustering algorithms (e.g., a Mini-batch K-means clustering algorithm), a recommendation algorithm (e.g., a Miniwise Hashing algorithm, or Euclidean Locality-Sensitive Hashing (LSH) algorithm), and/or an anomaly detection algorithm, such as a Local outlier factor. Additionally, machine-learning models can employ a dimensionality reduction approach, such as, one or more of: a Mini-batch Dictionary Learning algorithm, an Incremental Principal Component Analysis (PCA) algorithm, a Latent Dirichlet Allocation algorithm, and/or a Mini-batch K-means algorithm, etc.

FIG. 11B illustrates an example of using the trained ML model 1104. The input 1102 and/or instructions for modifying the input 1102 are applied as inputs to the trained ML model 1104 to generate the outputs, which can include the output 1106.

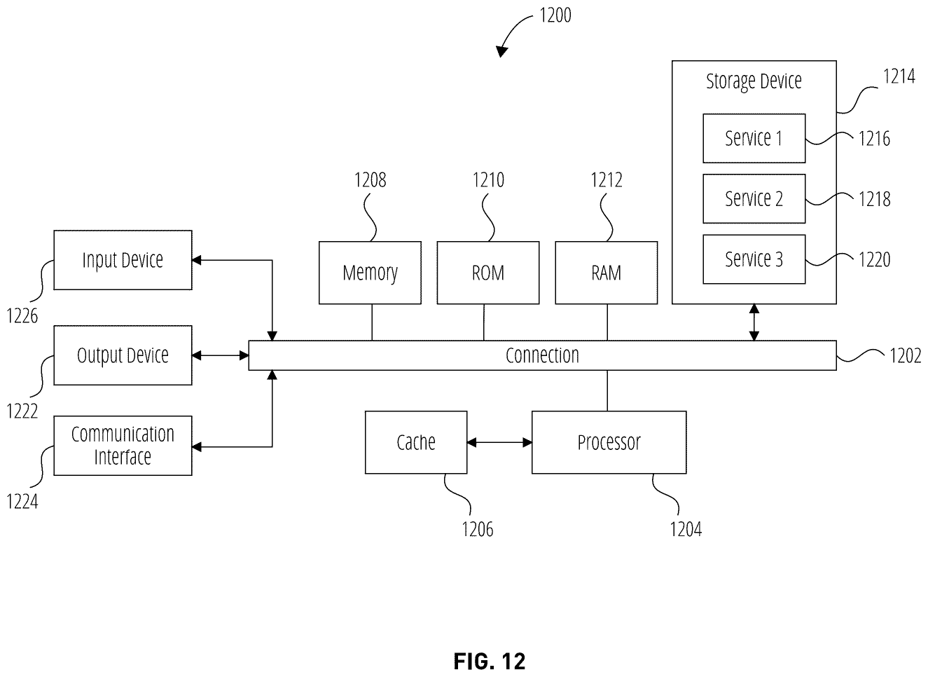

FIG. 12 shows an example of computing system 1200. The computing system 1200 can be system 100, system 400, or system 800. The computing system 1200 can be part of a distributed computing network in which several computers perform respective steps in method 300, method 500, or method 900 and/or the functions of system 100, system 400, or system 800. The computing system 1200 can be connected to the other parts of the distributed computing network via connection 1202 or communication interface 1224. Connection 1202 can be a physical connection via a bus, or a direct connection into processor 1204, such as in a chipset architecture. Connection 1202 can also be a virtual connection, networked connection, or logical connection.

In some embodiments, computing system 1200 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example computing system 1200 includes at least one processing unit (CPU or processor) 1204 and connection 1202 that couples various system components including system memory 1208, such as read-only memory (ROM) 1210 and random access memory (RAM) 1212 to processor 1204. Computing system 1200 can include a cache of high-speed memory 1206 connected directly with, in close proximity to, or integrated as part of processor 1204. Processor 1204 may essentially be a completely self-contained computing system, containing multiple cores or processors, a bus, memory controller, cache, etc. A multi-core processor may be symmetric or asymmetric.

Processor 1204 can include any general-purpose processor and a hardware service or software service, such as services 1216, 1218, and 1220 stored in storage device 1214, configured to control processor 1204 as well as a special-purpose processor where software instructions are incorporated into the actual processor design.

To enable user interaction, computing system 1200 includes an input device 1226, which can represent any number of input mechanisms, such as a microphone for speech, a touch-sensitive screen for gesture or graphical input, keyboard, mouse, motion input, speech, etc. Computing system 1200 can also include output device 1222, which can be one or more of a number of output mechanisms known to those of skill in the art. In some instances, multimodal systems can enable a user to provide multiple types of input/output to communicate with computing system 1200. Computing system 1200 can include a communication interface 1224, which can generally govern and manage the user input and system output. There is no restriction on operating on any particular hardware arrangement, and therefore the basic features here may easily be substituted for improved hardware or firmware arrangements as they are developed.

Storage device 1214 can be a non-volatile memory device and can be a hard disk or other types of computer-readable media that can store data that are accessible by a computer, such as magnetic cassettes, flash memory cards, solid state memory devices, digital versatile disks, cartridges, random access memories (RAMs), read-only memory (ROM), and/or some combination of these devices.

The storage device 1214 can include software services, servers, services, etc., that when the code that defines such software is executed by the processor 1204, it causes the system to perform a function. In some embodiments, a hardware service that performs a particular function can include the software component stored in a computer-readable medium in connection with the necessary hardware components, such processor 1204, connection 1202, output device 1222, etc., to carry out the function.

For clarity of explanation, in some instances, the present technology may be presented as including individual functional blocks including functional blocks comprising devices, device components, steps or routines in a method embodied in software, or combinations of hardware and software.

Any of the steps, operations, functions, or processes described herein may be performed or implemented by a combination of hardware and software services or services, alone or in combination with other devices. In some embodiments, a service can be software that resides in memory of system 100, system 400, or system 800 and performs one or more functions of method 300, method 500, or method 900 when a processor executes the software associated with the service. In some embodiments, a service is a program or a collection of programs that carry out a specific function. In some embodiments, a service can be considered a server. The memory can be a non-transitory computer-readable medium.

In some embodiments, the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Methods according to the above-described examples can be implemented using computer-executable instructions that are stored or otherwise available from computer-readable media. Such instructions can comprise, for example, instructions and data that cause or otherwise configure a general-purpose computer, special-purpose computer, or special-purpose processing device to perform a certain function or group of functions. Portions of computer resources used can be accessible over a network. The executable computer instructions may be, for example, binaries, intermediate format instructions such as assembly language, firmware, or source code. Examples of computer-readable media that may be used to store instructions, information used, and/or information created during methods according to described examples include magnetic or optical disks, solid-state memory devices, flash memory, USB devices provided with non-volatile memory, networked storage devices, and so on.

Devices implementing methods according to these disclosures can comprise hardware, firmware and/or software, and can take any of a variety of form factors. Typical examples of such form factors include servers, laptops, smartphones, small form factor personal computers, personal digital assistants, and so on. The functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are means for providing the functions described in these disclosures.

Embodiments of the present disclosure include various steps, which are described in this specification. The steps may be performed by hardware components or may be embodied in machine-executable instructions, which may be used to cause a general-purpose or special-purpose processor programmed with the instructions to perform the steps. Alternatively, the steps may be performed by a combination of hardware, software and/or firmware.

Various modifications and additions can be made to the exemplary embodiments discussed without departing from the scope of the present invention. For example, while the embodiments, also referred to as implementations or examples, described above refer to particular features, the scope of this invention also includes embodiments having different combinations of features and embodiments that do not include all of the described features. Accordingly, the scope of the present invention is intended to embrace all such alternatives, modifications, and variations together with all equivalents thereof.

While specific implementations are discussed, it should be understood that this is done for illustration purposes only. A person skilled in the relevant art will recognize that other components and configurations may be used without parting from the spirit and scope of the disclosure. Thus, the following description and drawings are illustrative and are not to be construed as limiting. Numerous specific details are described to provide a thorough understanding of the disclosure. However, in certain instances, well-known or conventional details are not described in order to avoid obscuring the description. References to one or an embodiment in the present disclosure can be references to the same embodiment or any embodiment; and, such references mean at least one of the embodiments.

Reference to “one embodiment” or “an embodiment” means that a particular feature, structure, or characteristic described in connection with the embodiment is included in at least one embodiment of the disclosure. The appearances of the phrase “in one embodiment”, or similarly “in one example” or “in one instance”, in various places in the specification are not necessarily all referring to the same embodiment, nor are separate or alternative embodiments mutually exclusive of other embodiments. Moreover, various features are described which may be exhibited by some embodiments and not by others.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. In some cases, synonyms for certain terms are provided. A recital of one or more synonyms does not exclude the use of other synonyms. The use of examples anywhere in this specification including examples of any terms discussed herein is illustrative only and is not intended to further limit the scope and meaning of the disclosure or of any example term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Additional features and advantages of the disclosure will be set forth in the description which follows, and in part will be obvious from the description, or can be learned by practice of the herein disclosed principles. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

What is claimed is:

1. A method that predicts battery-performance information for a battery, the method comprising:
applying both cycling data and electrodynamic parameters to a machine learning (ML) model, and, in response, outputting battery-performance information; and
providing the battery-performance information to a computing device that is configured to determine, based on the battery-performance information, an action to performed with respect to the battery, wherein
the cycling data is measured during charging and/or discharging of the battery.

2. The method of claim 1, wherein the action includes at least one of replacing the battery at a time determined based on the battery-performance information, an accident prevention action, a battery management action, managing a charging cycle, preventing overcharging, or preventing undercharging the battery.

3. The method of claim 1, further comprising:
applying the cycling data to another ML model, and, in response, outputting the electrodynamic parameters that are applied as inputs to the ML model, wherein
the another ML model has been trained using training data to predict the electrodynamic parameters, the training data including training cycling data associated with corresponding probing waveform data, and the another ML model having been trained by adjusting weighting coefficients in a neural network to optimize a loss function that represents a distance metric between electrodynamic parameters predicted based on the train cycling data and electrodynamic parameters calculated from the corresponding probing waveform data.

4. The method of claim 1, wherein:
the electrodynamic parameters are determined based on measurements when a probing waveform is applied to the battery, and
the electrodynamic parameters are based on one or more Lyapunov exponents corresponding to respective frequency ranges, one or more correlation dimensions, one or more sample entropies, one or more Hurst exponents, a fluctuation analysis, and/or a charge rate voltage slew.

5. The method of claim 1, wherein:
the ML model has been trained on training data that includes measured battery-performance information associated with corresponding training input data comprising training electrodynamic parameters and training cycling data, the training data being obtained from a corpus of historical measurements, and
the ML model is trained by adjusting weights in a neural network to minimize a loss function that includes a first term and a second term.

6. The method of claim 5, wherein the measured battery-performance information is a metric derived from measurements of respective batteries used to generate the corpus of historical measurements, and the metric selected from the group consisting of a state of charge (SOC) metric, a state of health (SOH) metric, and a remaining useful life (RUL) metric.

7. The method of claim 5, wherein:
the first term representing a distance metric between the measured battery-performance information and the battery-performance information that is output from the ML model in response to applying the corresponding training input data, and
the second term representing a distance metric between a simulated battery-performance information and the battery-performance information that is output from the ML model in response to applying the corresponding training input data.

8. The method of claim 5, wherein the training data further includes simulated battery-performance information generated by a physics-based model that predicts the simulated battery-performance information using the cycling data.

9. The method of claim 8, wherein the loss function includes a weighting term that determines a contribution of the first term relative to the second term, and a value of the weighting term is empirically derived to minimize non-physical predictions by the trained ML model.

10. The method of claim 1, wherein:
the electrodynamic parameters are determined based on measurements when a probing waveform is applied to the battery, and
the probing waveform periodically transitions from a charging period to a resting period and/or discharging period, during the charging period a voltage applied to the battery has a first pulse shape that on average is monotonically rising, and during the resting period and/or the discharging period the voltage applied to the battery has a second pulse shape that on average is monotonically falling.

11. The method of claim 10, wherein the first pulse shape and the second pulse shape are selected to include frequencies within a predefined range based on a frequency dependance of an impedance of the battery.

12. A method of generating battery cell characterization data, the method comprising:
inputting one or more scanning electron microscope (SEM) images of an electrode of the battery cell; analyzing the images to determine one or more degradation characteristics of the electrode; and
outputting a score corresponding to a level of the determined electrode degradation characteristics.

13. The method of claim 12, wherein:
the degradation characteristics of the electrode comprise one selected from a group consisting of plating, surface area, surface roughness, and dendrite growth, and
analyzing the images comprises providing the images to a convolutional neural network (CNN) configured to detect image features related to degradation characteristics of the electrode.

14. The method of claim 12, further comprising:
outputting at least one selected from a group consisting of an average of multiple scores, a standard deviation, a median score, a minimum score, and a maximum score from multiple SEM images of a single battery cell.

15. A computing apparatus comprising:
a processor; and
a memory storing instructions that, when executed by the processor, configure the apparatus to:
apply both cycling data and electrodynamic parameters to a machine learning (ML) model, and, in response, outputting battery-performance information; and
provide the battery-performance information to a computing device that is configured to determine, based on the battery-performance information, an action to performed with respect to the battery, wherein
the cycling data is measured during charge and/or discharging of the battery.

16. The computing apparatus of claim 15, wherein the action includes at least one of replacing the battery at a time determined based on the battery-performance information, an accident prevention action, a battery management action, managing a charging cycle, preventing overcharging, or preventing undercharging the battery.

17. The computing apparatus of claim 15, wherein the instructions further configure the apparatus to:
apply the cycling data to another ML model, and, in response, outputting the electrodynamic parameters that are applied as inputs to the ML model, wherein
the another ML model has been trained using training data to predict the electrodynamic parameters, the training data including training cycling data associated with corresponding probing waveform data, and the another ML model having been trained by adjusting weighting coefficients in a neural network to optimize a loss function that represents a distance metric between electrodynamic parameters predicted based on the train cycling data and electrodynamic parameters calculated from the corresponding probing waveform data.

18. The computing apparatus of claim 15, wherein:
the electrodynamic parameters are determined based on measurements when a probing waveform is applied to the battery, and
the electrodynamic parameters are based on one or more Lyapunov exponents corresponding to respective frequency ranges, one or more correlation dimensions, one or more sample entropies, one or more Hurst exponents, a fluctuation analysis, and/or a charge rate voltage slew.

19. The computing apparatus of claim 15, wherein:
the ML model has been trained on training data that includes measured battery-performance information associated with corresponding training input data comprising training electrodynamic parameters and training cycling data, the training data being obtained from a corpus of historical measurements, and
the ML model is trained by adjusting weights in a neural network to minimize a loss function that includes a first term and a second term.

20. The computing apparatus of claim 19, wherein:
the first term representing a distance metric between the measured battery-performance information and the battery-performance information that is output from the ML model in response to applying the corresponding training input data, and
the second term representing a distance metric between a simulated battery-performance information and the battery-performance information that is output from the ML model in response to applying the corresponding training input data.

21. The computing apparatus of claim 19, wherein the training data further includes simulated battery-performance information generated by a physics-based model that predicts the simulated battery-performance information using the cycling data.
